(19) United States
(12) Patent Application Publication
(10) Pub. No.: US 2026/0075800 A1
(43) Pub. Date: Mar. 12, 2026

(54) SEMICONDUCTOR MEMORY DEVICES AND METHODS OF MANUFACTURING THE SAME

(71) Applicant: Samsung Electronics Co., Ltd., Suwon-si (KR)

(72) Inventor: Suk-Hyun LIM, Suwon-si (KR)

(73) Assignee: Samsung Electronics Co., Ltd., Suwon-si (KR)

(21) Appl. No.: 19/302,551

(22) Filed: Aug. 18, 2025

(30) Foreign Application Priority Data
Sep. 6, 2024 (KR) 10-2024-0121859

(51) Int. Cl. H10B 12/00

(52) U.S. Cl. CPC H10B 12/315; H10B 12/05

(57) ABSTRACT

A semiconductor memory device includes active patterns in a first direction and a second direction to form rows and columns, the active patterns including first and second vertical semiconductor patterns spaced apart from each other, bit lines extending in the second direction and connected to lower surfaces of the first and second vertical semiconductor patterns of the active patterns of each of the columns, word lines extending in the first direction, and between the first vertical semiconductor patterns and the second vertical semiconductor patterns of the active patterns of each of the rows, word line insulation patterns between the word lines and the active patterns, the word line insulation patterns not covering upper surfaces of the word lines, back gate lines extending in the first direction and between the adjacent rows, and back gate insulation patterns between the back gate lines and the active patterns, extending in the first direction.

### CROSS-REFERENCE TO RELATED APPLICATION(S)

This U.S. non-provisional application claims priority under 35 USC § 119 to Korean Patent Application No. 10-2024-0121859, filed on Sep. 6, 2024, in the Korean Intellectual Property Office, the disclosure of which is herein incorporated by reference in its entirety.

### BACKGROUND

The present application relates to semiconductor memory devices and methods of manufacturing the same.

Semiconductor devices may be key components used to control or amplify electrical signals in electronic devices. Various types of semiconductor devices are being developed to perform various functions of electronic devices. As the design rules of semiconductor devices are altered, the manufacturing technology of semiconductor devices is developing in the direction of improving integration, operating speed, and yield. Accordingly, vertical channel transistors have been proposed to increase the integration of transistors in semiconductor devices.

### SUMMARY

The present application is directed to providing semiconductor memory devices with improved integration and electrical characteristics, and methods of manufacturing the same.

A semiconductor memory device according to some example embodiments of the present application may include active patterns arranged in a first direction and a second direction intersecting the first direction to form rows and columns, each of the active patterns including first and second vertical semiconductor patterns spaced apart from each other and extending in a third direction perpendicular to the first and second directions, and a connecting portion between upper end portions of the first and second vertical semiconductor patterns and integrally connected to the upper end portions, bit lines arranged in the first direction, each extending in the second direction, and connected to lower surfaces of the first and second vertical semiconductor patterns of the active patterns of each of the columns, word lines arranged in the second direction, each extending in the first direction, and between the first vertical semiconductor patterns and the second vertical semiconductor patterns of the active patterns of each of the rows, word line insulation patterns each between each of the word lines and the active patterns of each of the rows; back gate lines arranged in the second direction, each extending in the first direction, and between the adjacent rows, and back gate insulation patterns each between each of the back gate lines and the active patterns and extending in the first direction.

Each of the first and second vertical semiconductor patterns may include a channel region, a first source/drain region, and a second source/drain region, the first source/drain region may be in an upper end portion of each of the first and second vertical semiconductor patterns, the second source/drain region may be in a lower end portion of each of the first and second vertical semiconductor patterns, and the channel region may be between the first source/drain region and the second source/drain region.

The semiconductor memory device may further include a data storage pattern on upper surfaces of the first and second vertical semiconductor patterns of each of the active patterns and electrically connected to the first and second vertical semiconductor patterns.

The data storage pattern may be a capacitor.

The semiconductor memory device may further include word line capping patterns each covering each of the upper surfaces of the word lines and extending in the first direction, wherein upper surfaces of the word line capping patterns may be coplanar or substantially coplanar with upper surfaces of the first and second vertical semiconductor patterns.

The word line insulation patterns may include a different material from the word line capping patterns.

The semiconductor memory device may further include back gate capping patterns each covering each of upper surfaces of the back gate lines and extending in the first direction.

The first and second vertical semiconductor patterns may be in a monocrystalline state.

A semiconductor memory device according to some example embodiments of the present application may include active patterns arranged in a first direction and a second direction intersecting the first direction to form rows and columns, each of the active patterns including first and second vertical semiconductor patterns spaced apart from each other and extending in a third direction perpendicular to the first and second directions and a connecting portion between upper end portions of the first and second vertical semiconductor patterns and integrally connected to the upper end portions, bit lines arranged in the first direction, each extending in the second direction, and connected to lower surfaces of the first and second vertical semiconductor patterns of the active patterns of each of the columns, word lines arranged in the second direction, each extending in the first direction, and between the first vertical semiconductor patterns and the second vertical semiconductor patterns of the active patterns of each of the rows, word line insulation patterns each between each of the word lines and the active patterns of each of the rows, back gate lines arranged in the second direction, each extending in the first direction, and between the adjacent rows, and back gate insulation patterns each between each of the back gate lines and the active patterns and extending in the first direction.

The first and second vertical semiconductor patterns may include channel regions, a first source/drain region, and second source/drain regions, the first source/drain region may be in the upper end portions of the first and second vertical semiconductor patterns and the connecting portion, the second source/drain regions may be each in each of lower portions of the first and second vertical semiconductor patterns, and the channel regions may be defined between the first source/drain region and the second source/drain regions.

The semiconductor memory device may further include word line capping patterns each covering each of upper surfaces of the word lines and extending in the first direction, wherein upper surfaces of the word line capping patterns may be coplanar or substantially coplanar with lower surfaces of the connecting portions.

The semiconductor memory device may further include back gate capping patterns each covering each of upper surfaces of the back gate lines and extending in the first direction.

A method of manufacturing a semiconductor memory device according to some example embodiments of the present application may include forming first trenches extending in a first direction within a substrate to define preliminary active lines and forming back gate lines each filling each of the first trenches, forming second trenches crossing the first trenches and the preliminary active lines within the substrate to form preliminary active patterns, the preliminary active patterns being arranged in a first direction and a second direction intersecting the first direction to form rows and columns, patterning the preliminary active patterns to form third trenches extending in the first direction and active patterns, each of the active patterns including first and second vertical semiconductor patterns spaced apart from each other, and each of the third trenches being formed between the first vertical semiconductor patterns and second vertical semiconductor patterns of the active patterns of each of the rows, forming a word line insulation film on the substrate having the third trenches and the active patterns, and forming word lines each filling each of the third trenches on the word line insulation film.

The method may further include, before the forming of the third trenches, forming separation insulation patterns within the second trenches, wherein the patterning of the preliminary active patterns may include patterning the preliminary active patterns and the separation insulation patterns to form the third trenches and the active patterns, and each of the third trenches may be formed between the first vertical semiconductor patterns and second vertical semiconductor patterns of the active patterns of each of the rows and within the separation insulation patterns of each of the rows.

The method may further include, before the forming of the word lines, forming word line capping patterns covering upper surfaces of the word lines.

The method may further include, after the forming of the word lines, grinding a lower surface of the substrate until lower surfaces of the first and second vertical semiconductor patterns are exposed, and forming bit lines on the lower surfaces of the first and second vertical semiconductor patterns.

The method may further include, after the forming of the bit lines, forming a data storage pattern on upper surfaces of the first and second vertical semiconductor patterns of each of the active patterns.

The data storage pattern may be a capacitor.

Levels of bottom surfaces of the third trenches may be lower than levels of lower surfaces of the first and second vertical semiconductor patterns.

Levels of bottom surfaces of the third trenches may be higher than levels of lower surfaces of the first and second vertical semiconductor patterns, and each of the active patterns may further include a connecting portion between upper end portions of the first and second vertical semiconductor patterns and integrally connected to the upper end portions.

### BRIEF DESCRIPTION OF DRAWINGS

FIG. 1 is a perspective view showing a semiconductor memory device according to some example embodiments of the present application.

FIG. 2 is a plan view showing a semiconductor memory device according to some example embodiments of the present application.

FIG. 3 is a cross-sectional view taken along line A-A′ of FIG. 2.

FIG. 4 is a cross-sectional view taken along line B-B′ of FIG. 2.

FIGS. 5 and 6 show a semiconductor memory device according to some example embodiments of the present application, which are cross-sectional views respectively corresponding to lines A-A′ and B-B′ of FIG. 2.

FIG. 7 shows a semiconductor memory device according to some example embodiments of the present application, which is a cross-sectional view corresponding to line A-A′ of FIG. 2.

FIGS. 8A, 9A, 10A to 22A are plan views showing a method of manufacturing a semiconductor memory device according to some example embodiments of the present application.

FIGS. 8B, 9B, 10B to 22B are cross-sectional views taken along lines A-A′ and B-B′ of FIGS. 8A to 22A, respectively.

FIGS. 23A, 24A to 28A are plan views showing a method of manufacturing a semiconductor memory device according to some example embodiments of the present application.

FIGS. 23B, 24B to 28B are cross-sectional views taken along lines A-A′ and B-B′ of FIGS. 23A to 28A, respectively.

### DETAILED DESCRIPTION

Hereinafter, some example embodiments of the present application will be described in more detail with reference to the accompanying drawings.

A semiconductor memory device according to some example embodiments of the present application may be a storage device based on semiconductor elements. For example, the semiconductor memory device may be a volatile memory such as a dynamic random access memory (DRAM), a synchronous DRAM (SDRAM), a double data rate SDRAM (DDR SDRAM), a low power double data rate SDRAM (LPDDR SDRAM), a graphics double data rate SDRAM (GDDR SDRAM), a DDR2 SDRAM, a DDR3 SDRAM, a DDR4 SDRAM, or a thyristor random access memory (TRAM), or a non-volatile memory such as a phase change random access memory (PRAM), a magnetic random access memory (MRAM), or a resistive random access memory (RRAM).

A semiconductor memory device according to some example embodiments of the present application may include memory cells including a vertical channel transistor (VCT). The vertical channel transistor may refer to a transistor in which a semiconductor pattern extends in a direction perpendicular to an upper surface of a semiconductor substrate.

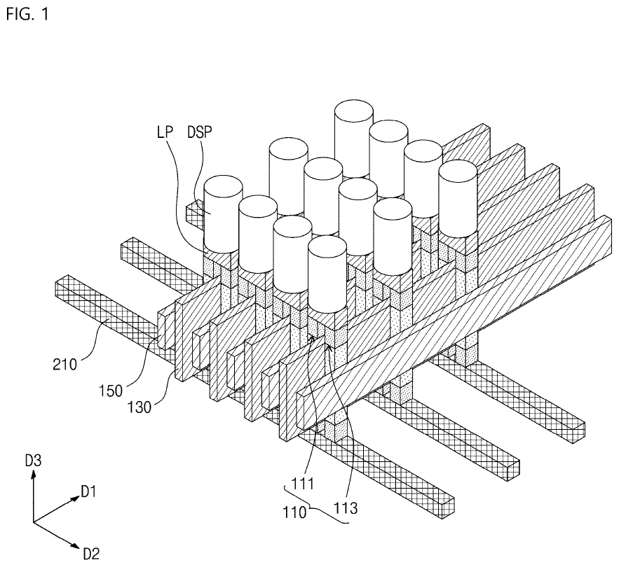

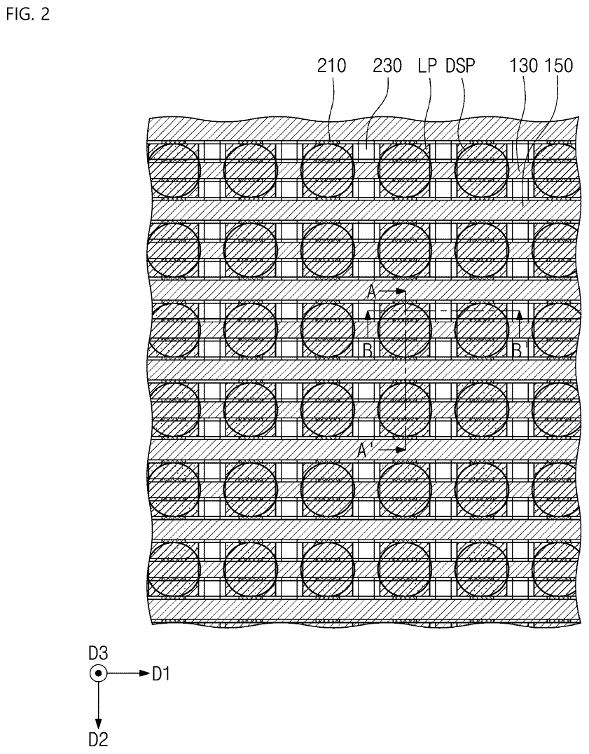

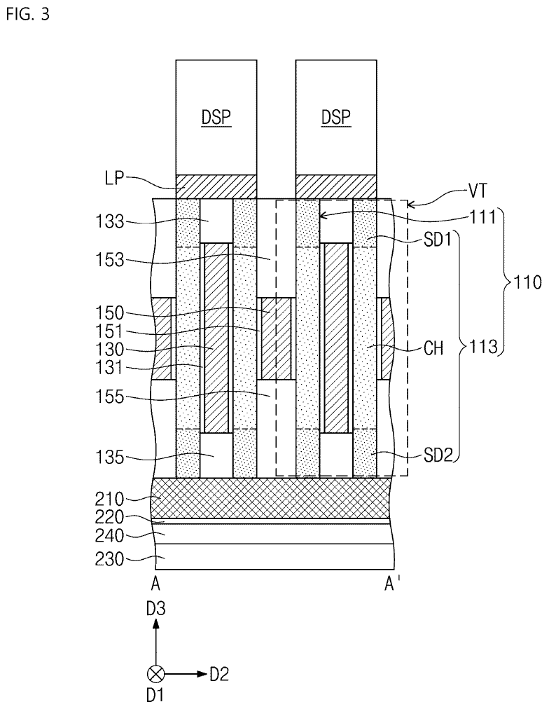

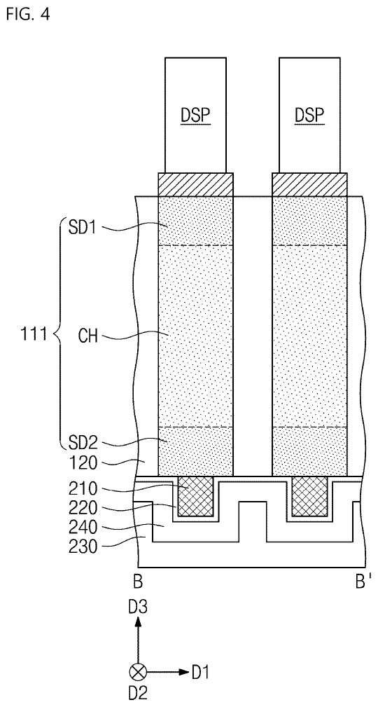

FIG. 1 is a perspective view showing a semiconductor memory device according to some example embodiments of the present application. FIG. 2 is a plan view showing a semiconductor memory device according to some example embodiments of the present application. FIG. 3 is a cross-sectional view taken along line A-A′ of FIG. 2. FIG. 4 is a cross-sectional view taken along line B-B′ of FIG. 2.

Referring to FIGS. 1 to 4, a semiconductor memory device according to some example embodiments of the present application may include an active pattern 110, a bit line 210, a word line 130, a word line insulation pattern 131, a back gate line 150, a back gate insulation pattern 151, and a data storage pattern DSP.

An active pattern 110 may be provided. The active pattern 110 may function as a vertical channel transistor (VCT) of the semiconductor memory device according to some example embodiments of the present application. In some example embodiments, the semiconductor memory device may include a plurality of active patterns 110. The active patterns 110 may be arranged in a first direction D1 and a second direction D2 intersecting the first direction D1 to form rows and columns in a plan view.

The active pattern 110 may include first and second vertical semiconductor patterns 111 and 113. The first and second vertical semiconductor patterns 111 and 113 may extend in a third direction D3 perpendicular to the first and second directions D1 and D2. In some example embodiments, each of the first and second vertical semiconductor patterns 111 and 113 may have a rectangular shape in a plan view, but is not limited thereto. Each of the first and second vertical semiconductor patterns 111 and 113 may have, for example, a quadrangular shape with rounded corners in a plan view.

The first and second vertical semiconductor patterns 111 and 113 may each include a first source/drain region SD1, a second source/drain region SD2, and a channel region CH. The first source/drain region SD1 may be formed in upper end portions of each of the first and second vertical semiconductor patterns 111 and 113, and the second source/drain region SD2 may be formed in lower end portions of each of the first and second vertical semiconductor patterns 111 and 113. Here, the upper end portions may be end portions of the first and second vertical semiconductor patterns 111 and 113 in the third direction D3, and the lower end portions may be end portions of the first and second vertical semiconductor patterns 111 and 113 in an opposite direction of the third direction D3.

In some example embodiments, the first source/drain region SD1 may be connected to a landing pad LP, and the second source/drain region SD2 may be connected to the bit line 210. Each of the first and second source/drain regions SD1 and SD2 may function as a source and/or a drain to supply and/or discharge a carrier that carry a current. Here, the carrier may be an electron or a hole. The channel region CH may function as a path through which the carrier moves. For example, the first source/drain region SD1 may function as a source, the second source/drain region SD2 may function as a drain, and the channel region CH may function as a path through which the carrier moves between the source and the drain. The first and second source/drain regions SD1 and SD2 may be regions doped with impurities having a conductivity type different from that of the channel region CH. For example, when the channel region CH includes impurities of a first conductivity type, the first and second source/drain regions SD1 and SD2 may be regions doped with impurities of a second conductivity type opposite to the first conductivity type. For example, the first conductivity type impurities may be p-type impurities such as boron (B) that is a group III element, and the second conductivity type impurities may include n-type impurities such as phosphorus (P) and/or arsenic (As) that are group V elements.

The active pattern 110 may include a semiconductor material, for example, silicon (Si), germanium (Ge), silicon-germanium (Si—Ge), etc. The active pattern 110 may include an oxide semiconductor material. The oxide semiconductor material may be at least one of, for example, InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, and IGZO (Indium Gallium Zinc Oxide). The active pattern 110 may include a single layer or multiple layers of the oxide semiconductor material. The active pattern 110 may include an amorphous, crystalline, or polycrystalline oxide semiconductor material, but is not limited thereto. In some example embodiments, the active pattern 110 may include a monocrystalline semiconductor material. Therefore, the first and second vertical semiconductor patterns 111 and 113 may be in a monocrystalline state. In some example embodiments, the active pattern 110 may have a bandgap energy larger than that of silicon. In some example embodiments, the active pattern 110 may include a two-dimensional semiconductor material. The two-dimensional semiconductor material may include, for example, graphene, MoS₂, WS₂, MoSe₂, WSe₂, or a combination thereof.

The bit line 210 may be provided to extend in the second direction D2. In some example embodiments, the semiconductor memory device may include a plurality of bit lines 210, and the bit lines 210 may be arranged in the first direction D1. The bit lines 210 may be spaced apart from each other at regular intervals in the first direction D1.

Each of the bit lines 210 may be provided on lower surfaces of the first and second vertical semiconductor patterns 111 and 113 of each of the active pattern 110. More specifically, each of the bit lines 210 may be arranged in the first direction D1, may extend in the second direction D2, and may be connected to the lower surfaces of the first and second vertical semiconductor patterns 111 and 113 of each of the columns of the active patterns 110.

In some example embodiments, each of the bit lines 210 may include a buried conductive pattern, a contact pattern, a metal pattern, and a hard mask pattern sequentially that are stacked in the opposite direction of the third direction D3. The buried conductive pattern may include polysilicon doped with impurities. The contact pattern may include at least one of, for example, tantalum (Ta), tantalum nitride (TaN), titanium (Ti), a titanium nitride (TiN), a titanium silicon nitride (TiSiN), ruthenium (Ru), cobalt (Co), nickel (Ni), nickel boron (NiB), tungsten (W), a tungsten nitride (WN), a tungsten carbonitride (WCN), zirconium (Zr), a zirconium nitride (ZrN), vanadium (V), a vanadium nitride (VN), niobium (Nb), a niobium nitride (NbN), platinum (Pt), iridium (Ir), rhodium (Rh), and a two-dimensional (2D) material. The metal pattern may include at least one of a metal material (for example, Al, Cu, Ti, Ta, Ru, W, Mo, Pt, Ni, Co), a conductive metal nitride (for example, TiN, TaN, WN, NbN, TiAIN, TiSiN, TaSIN, RuTiN), a conductive metal silicide, and/or a conductive metal oxide (for example, PtO, RuO₂, IrO₂, SRO (SrRuO₃), BSRO ((Ba,Sr) RuO₃), CRO (CaRuO₃), LSCo). The hard mask pattern may include an insulating material such as a silicon nitride or a silicon oxynitride.

The word line 130 may be provided to extend in the first direction D1. In some example embodiments, the semiconductor memory device may include a plurality of word lines 130, and the word lines 130 may be arranged in the second direction D2. The word lines 130 may be spaced apart from each other at regular intervals in the second direction D2.

Each of the word lines 130 may be provided between the first and second vertical semiconductor patterns 111 and 113 of each of the active patterns 110. More specifically, each of the word lines 130 may be arranged in the second direction D2, may extend in the first direction D1, and may be provided between the first and second vertical semiconductor patterns 111 and 113 of each of the rows of the active patterns 110.

The word line 130 may include, for example, a metal, a conductive metal nitride, a conductive metal silicide, a conductive metal oxide, polysilicon doped with impurities, or a combination thereof.

The word line insulation pattern 131 may be provided between the word line 130 and the first and second vertical semiconductor patterns 111 and 113 to extend in the first direction D1. The word line insulation pattern 131 may electrically isolate the word line 130 from the first and second vertical semiconductor patterns 111 and 113. In some example embodiments, the semiconductor memory device may include a plurality of word line insulation patterns 131, and the word line insulation patterns 131 may be arranged in the second direction D2.

Each of the word line insulation patterns 131 may be disposed between each of the word lines 130 and each of the active patterns 110 of the rows. More specifically, each of the word line insulation patterns 131 may be provided between the first and second vertical semiconductor patterns 111 and 113 included in each of the active patterns 110 of the rows and each of the word lines 130. In some example embodiments, the word line insulation patterns 131 may not cover upper surfaces of the word lines 130.

The word line insulation pattern 131 may include, for example, a silicon oxide, a silicon nitride, a silicon oxynitride, a high dielectric constant material with a higher dielectric constant than the silicon oxide, or a combination thereof.

In some example embodiments, a word line capping pattern 133 may be provided between the adjacent first and second vertical semiconductor patterns 111 and 113 to extend in the first direction D1. The word line capping pattern 133 may electrically isolate the adjacent first and second vertical semiconductor patterns 111 and 113 from each other. The word line capping pattern 133 may be provided on the word line 130. More specifically, a plurality of word line capping patterns 133 may be provided to be arranged in the second direction D2, and each of the word line capping patterns 133 may cover the upper surface of each of the word lines 130 and extend in the first direction D1. In addition, upper surfaces of the word line capping patterns 133 may be coplanar or substantially coplanar with upper surfaces of the first and second vertical semiconductor patterns 111 and 113.

The word line capping pattern 133 may include, for example, a silicon oxide, a silicon nitride, a silicon oxynitride, a high dielectric constant material with a higher dielectric constant than the silicon oxide, or a combination thereof.

In some example embodiments, the word line insulation pattern 131 may include a material different from the word line capping pattern 133. For example, when the word line insulation pattern 131 includes a silicon oxide, the word line capping pattern 133 may include a high dielectric constant material with a higher dielectric constant than the silicon oxide.

The back gate line 150 may be provided between the adjacent active patterns 110, to extend in the first direction D1. In some example embodiments, the semiconductor memory device may include a plurality of back gate lines 150, and the back gate lines 150 may be arranged in the second direction D2. The back gate lines 150 may be spaced apart from each other at regular intervals in the second direction D2.

Each of the back gate lines 150 may be provided between the rows of the adjacent active patterns 110. More specifically, each of the back gate lines 150 may be provided between the first vertical semiconductor patterns 111 present in one row of the active patterns 110 and the second vertical semiconductor patterns 113 present in another row adjacent to the one row of the active patterns 110. Therefore, the active patterns 110 present in each of the adjacent rows may share the back gate line 150.

The back gate line 150 may include, for example, a metal, a conductive metal nitride, a conductive metal silicide, a conductive metal oxide, polysilicon doped with impurities, or a combination thereof.

In some example embodiments, a negative voltage may be applied to the back gate line 150 during the operation of the semiconductor memory device, thereby increasing the threshold voltage of the vertical channel transistor. As a result, since the back gate line 150 can control the threshold voltage, the threshold voltage can be decreased as the vertical channel transistor is miniaturized, thereby preventing or reducing leakage current characteristics from degradation.

The back gate insulation pattern 151 may be provided between the back gate line 150 and the adjacent active patterns 110. The back gate insulation pattern 151 may electrically isolate the back gate line 150 from the adjacent active patterns 110. In some example embodiments, the semiconductor memory device may include a plurality of back gate insulation patterns 151, and the back gate insulation patterns 151 may be arranged in the second direction D2.

Each of the back gate insulation patterns 151 may be disposed between each of the back gate lines 150 and the active patterns 110. More specifically, each of the back gate insulation patterns 151 may extend in the first direction D1 and be provided among the first vertical semiconductor patterns 111 present in one row of the active patterns 110, the second vertical semiconductor patterns 113 present in another row adjacent to the one row of active patterns 110, and the back gate lines 150 provided between the first and second vertical semiconductor patterns 111 and 113. In some example embodiments, the back gate insulation patterns 151 may not cover upper surfaces of the back gate lines 150.

The back gate insulation pattern 151 may include, for example, a silicon oxide, a silicon nitride, a silicon oxynitride, a high dielectric constant material with a higher dielectric constant than the silicon oxide, or a combination thereof.

In some example embodiments, a back gate capping pattern 153 may be provided between the adjacent active patterns to extend in the first direction D1. The back gate capping pattern 153 may electrically isolate the adjacent active patterns 110 from each other. The back gate capping pattern 153 may be provided on the back gate line 150. More specifically, a plurality of back gate capping patterns 153 may be provided to be arranged in the second direction D2, and each of the back gate capping patterns 153 may cover the upper surface of each of the back gate lines 150 and the upper surfaces of the back gate insulation patterns 151 and extend in the first direction D1. In addition, upper surfaces of the back gate capping patterns 153 may be coplanar or substantially coplanar with the upper surfaces of the first and second vertical semiconductor patterns 111 and 113.

The back gate capping pattern 153 may include, for example, a silicon oxide, a silicon nitride, a silicon oxynitride, a high dielectric constant material with a higher dielectric constant than the silicon oxide, or a combination thereof.

In some example embodiments, the back gate insulation pattern 151 may include a material different from the back gate capping pattern 153. For example, when the back gate insulation pattern 151 includes a silicon oxide, the back gate capping pattern 153 may include a high dielectric constant material with a higher dielectric constant than the silicon oxide.

In some example embodiments, a separation insulation pattern 120 may be provided between the active patterns 110 of each of the rows. More specifically, the separation insulation pattern 120 may be provided between the first vertical semiconductor patterns 111 in the first direction D1 and between the second vertical semiconductor patterns 113 in the first direction D1, between the active patterns 110 present in each of the rows. A lower surface of the separation insulation pattern 120 may be coplanar or substantially coplanar with the lower surfaces of the first and second vertical semiconductor patterns 111 and 113. In some example embodiments, the separation insulation pattern 120 may include a material different from the word line insulation pattern 131.

In some example embodiments, a first dielectric pattern 155 may be provided between the bit line 210 and the back gate line 150. A lower surface of the first dielectric pattern 155 may be in contact with the bit line 210. In other words, the lower surface of the first dielectric pattern 155 may be coplanar or substantially coplanar with an upper surface of the bit line 210. In some example embodiments, a level of an upper surface of the first dielectric pattern 155 may be higher than a level of an upper surface of the second dielectric pattern 135, but is not limited thereto. The first dielectric pattern 155 may extend in the first direction D1 to be parallel to the back gate line 150.

In some example embodiments, the second dielectric pattern 135 may be provided between the bit line 210 and the word line 130. A lower surface of the second dielectric pattern 135 may be in contact the bit line 210. In other words, the lower surface of the second dielectric pattern 135 may be coplanar or substantially coplanar with the upper surface of the bit line 210. The second dielectric pattern 135 may be provided between the lower portions of the first and second vertical semiconductor patterns 111 and 113. The second dielectric pattern 135 may extend in the first direction D1 to be parallel to the word line 130.

The separation insulation pattern 120, the first dielectric pattern 155, and the second dielectric pattern 135 may include an insulating material. The separation insulation pattern 120, the first dielectric pattern 155, and the second dielectric pattern 135 may include, for example, a silicon oxide, a silicon nitride, a silicon oxynitride, or a combination thereof.

In some example embodiments, a bit line insulation pattern 220 may be provided on lower surfaces of the bit lines 210. The bit line insulation pattern 220 may be a film in which an insulating material is conformally formed on the lower surfaces of the bit lines 210, the lower surfaces of the first dielectric patterns 155, the lower surfaces of the second dielectric patterns 135, the lower surfaces of the first vertical semiconductor patterns 111, and the lower surfaces of the second vertical semiconductor patterns 113. The bit line insulation pattern 220 may include at least one of, for example, a silicon oxide, a silicon nitride, a silicon oxynitride, and/or a low dielectric constant insulating material.

In some example embodiments, a dielectric film 240 may be provided on the lower surfaces of the bit lines 210. The dielectric film 240 may be a film formed conformally on a lower surface of the bit line insulation pattern 220. The dielectric film 240 may include, for example, a silicon oxide, a silicon nitride, a silicon oxynitride, and/or a high dielectric constant material including a metal.

In some example embodiments, a gap structure 230 may be provided between the bit lines 210 and on the dielectric film 240. In some example embodiments, the gap structure 230 may function as a shielding line of the semiconductor memory device to reduce coupling noise between the adjacent bit lines 210. The gap structure 230 may extend in the second direction D2 between the bit lines 210 and on the dielectric film 240. The gap structure 230 may be made of a conductive material and may include (or define) an air gap therein.

In some example embodiments, a landing pad LP may be provided on each of the active patterns 110. More specifically, each of the landing pads LP may be provided on the upper surfaces of the first and second vertical semiconductor patterns 111 and 113. Each of the landing pads LP may be arranged in a matrix form in the first direction D1 and the second direction D2 in a plan view. In some example embodiments, each of the landing pads LP may have a rectangular shape in a plan view, but is not limited thereto, and may have various shapes, for example, a circular shape, an oval shape, a rectangular shape, a square shape, a diamond shape, or a hexagonal shape, etc. In some example embodiments, the landing pad LP may be omitted. The landing pad LP may include doped polysilicon, Al, Cu, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrO, RuO, or a combination thereof, but is not limited thereto.

The data storage pattern DSP may be provided on the landing pad LP. More specifically, the data storage pattern DSP may be provided on the upper surfaces of the first and second vertical semiconductor patterns 111 and 113 of each of the active patterns 110 to be electrically connected to the first and second vertical semiconductor patterns 111 and 113. The data storage patterns DSP may be arranged in a matrix form in the first direction D1 and the second direction D2. In some example embodiments, the data storage pattern DSP may completely overlap the landing pad LP, but is not limited thereto. The data storage pattern DSP may, for example, partially overlap the landing pad LP. The data storage pattern DSP may be in contact with the entire upper surface of the landing pad LP or a portion of the upper surface of the landing pad LP.

In some example embodiments, the data storage patterns DSP may be variable resistance patterns that can be switched between two resistance states by electrical pulses applied to a memory element. For example, the data storage patterns DSP may include a phase-change material whose crystalline state changes according to the amount of current, perovskite compounds, a transition metal oxide, magnetic materials, ferromagnetic materials, and/or antiferromagnetic materials. In addition, in some example embodiments, the data storage pattern DSP may be a capacitor.

Each of the memory cells of the semiconductor memory device according to some example embodiments of the present application may include a selection element VT and the data storage pattern DSP. Here, the selection element VT may be a vertical channel transistor. As shown in FIG. 3, one of the selection element VT may include the first vertical semiconductor pattern 111, the second vertical semiconductor pattern 113, the word line 130, and a portion of the back gate line 150. The selection elements VT in the memory cells may share the back gate line 150.

A semiconductor memory device according to some example embodiments of the present application may provide with active patterns each including the first and second vertical semiconductor patterns, and each of the first and second vertical semiconductor patterns 111 and 113 may include the channel region CH. In addition, the word line 130 may be provided between the first and second vertical semiconductor patterns 111 and 113 that are included in the active pattern 110. Therefore, such that the channel regions CH may each be provided on both side surfaces of the word line 130. In addition, the back gate line 150 may be provided between the adjacent active patterns 110. Therefore, since the adjacent selection elements VT can share the back gate line 150, a leakage current that may occur in portions of the channel regions CH of the active patterns 110 can be controlled. In addition, since the number of word lines 130 and the number of back gate lines 150 disposed in one memory cell can be reduced, it is possible to improve integration in a process.

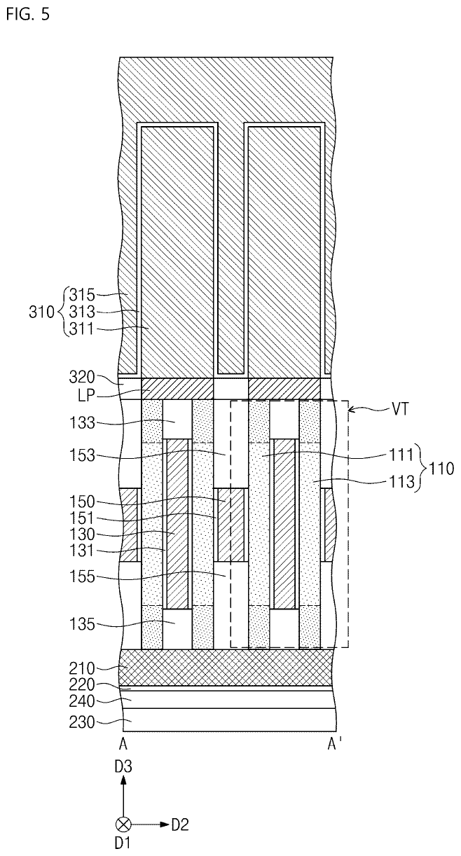

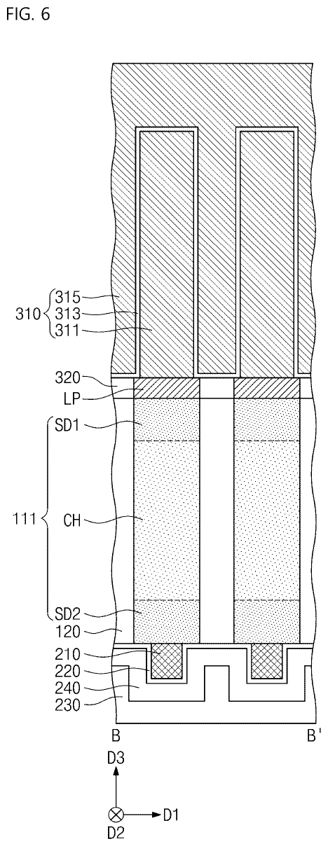

FIGS. 5 and 6 show a semiconductor memory device according to some example embodiments of the present application, which are cross-sectional views respectively corresponding to lines A-A′ and B-B′ of FIG. 2. For convenience of explanation, the below example embodiments will be described with a focus on differences from the above-described example embodiments.

Referring to FIGS. 5 and 6, the data storage pattern DSP of a semiconductor memory device according to some example embodiments of the present application may be a capacitor 310.

The capacitor 310 may be provided on the upper surfaces of the first and second vertical semiconductor patterns 111 and 113 of each of the active patterns 110. Here, the upper surfaces may be the surfaces in the third direction D3 of the first and second vertical semiconductor patterns 111 and 113. The capacitor 310 may store signals transmitted from transistors in a peripheral circuit structure (e.g., row and column decoders, a sense amplifier, etc.) of the semiconductor memory device. The capacitor 310 may be used as an information storage element electrically connected to the transistor. For example, the capacitor 310 may store charge under the control of the transistor. In some example embodiments, the capacitor 310 may include a storage electrode 311, a capacitor dielectric film 313, and a plate electrode 315.

The storage electrode 311 may be formed as a plurality of electrodes spaced apart from each other in the first direction D1 and the second direction D2 and may be in contact with the upper surface of each of the corresponding first and second vertical semiconductor patterns 111 and 113. The storage electrodes 311 may be spaced apart from each other at regular intervals in the first direction D1 and the second direction D2. In other words, the storage electrodes 311 may be arranged in the first direction D1 and the second direction D2 in a plan view. The storage electrode 311 may include a conductive material. The storage electrode 311 may include, for example, a metal, a metal nitride, a metal silicide, or a combination thereof. Therefore, the capacitor 310 may be electrically connected to the active patterns 110.

The capacitor dielectric film 313 may be provided on the storage electrodes 311 and pad separation patterns 320. The capacitor dielectric film 313 may be conformally formed on the storage electrodes 311 and the pad separation patterns 320. Unlike what is shown, the capacitor dielectric film 313 may include a plurality of films. The capacitor dielectric film 313 may include, for example, a silicon oxide, a silicon nitride, a silicon oxynitride, a high dielectric constant material containing a metal, or a combination thereof.

The plate electrode 315 may be provided on the capacitor dielectric film 313. The plate electrode 315 may fill empty spaces between the storage electrodes 311. The plate electrode 315 may include doped n-type impurities or p-type impurities. The plate electrode 315 may include, for example, a metal, a metal nitride, a metal silicide, silicon-germanium doped with impurities, or a combination thereof.

In some example embodiments, the pad separation patterns 320 may be disposed between the landing pads LP. The pad separation patterns 320 may separate each of the adjacent landing pads LP from each other. Upper surfaces of the pad separation patterns 320 may be coplanar or substantially coplanar with the upper surfaces of the landing pads LP. The pad separation patterns 320 may include an insulating material. The pad separation patterns 320 may include, for example, a silicon oxide, a silicon nitride, a silicon oxynitride, or a combination thereof.

Each of the active patterns 110 of the semiconductor memory device according to some example embodiments of the present application may have the first and second vertical semiconductor patterns 111 and 113 that are separated and spaced apart from each other, but is not limited thereto. The first and second vertical semiconductor patterns 111 and 113 of each of the active patterns 110 may be connected to each other through, for example, a separate connecting portion.

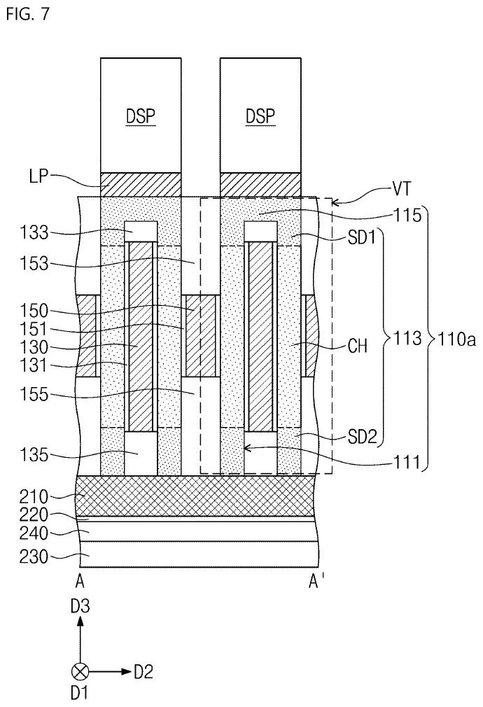

FIG. 7 shows a semiconductor memory device according to some example embodiments of the present application, which is a cross-sectional view corresponding to line A-A′ of FIG. 2. For convenience of explanation, the below example embodiments will be described with a focus on differences from the above-described example embodiments.

Referring to FIG. 7, an active pattern 110a may further include a connecting portion 115. The connecting portion 115 may be provided between the upper end portions of the first and second vertical semiconductor patterns 111 and 113 of the active pattern 110a and integrally connected to the upper end portions. In some example embodiments, an upper surface of the connecting portion 115 may be coplanar or substantially coplanar with the upper surfaces of the first and second vertical semiconductor patterns 111 and 113.

The connecting portion 115 may include the same material as the first and second vertical semiconductor patterns 111 and 113. The connecting portion 115 may include, for example, a semiconductor material such as silicon (Si), germanium (Ge), silicon-germanium (Si—Ge), an oxide semiconductor material, and/or a two-dimensional semiconductor material.

In some example embodiments, the first source/drain region SD1 may be provided in the connecting portion 115. Therefore, the first source/drain region SD1 may be connected in each of the active patterns 110a.

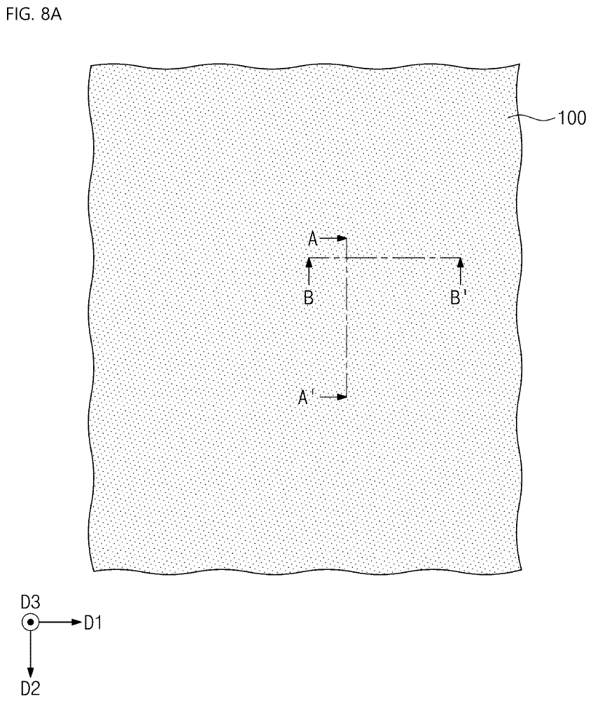

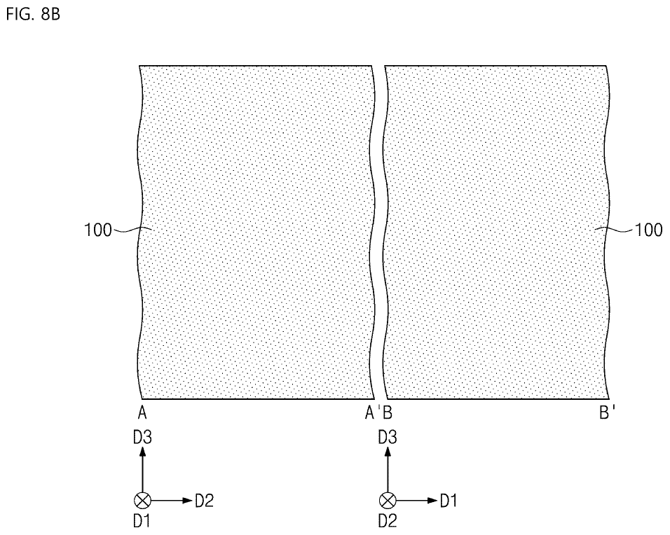

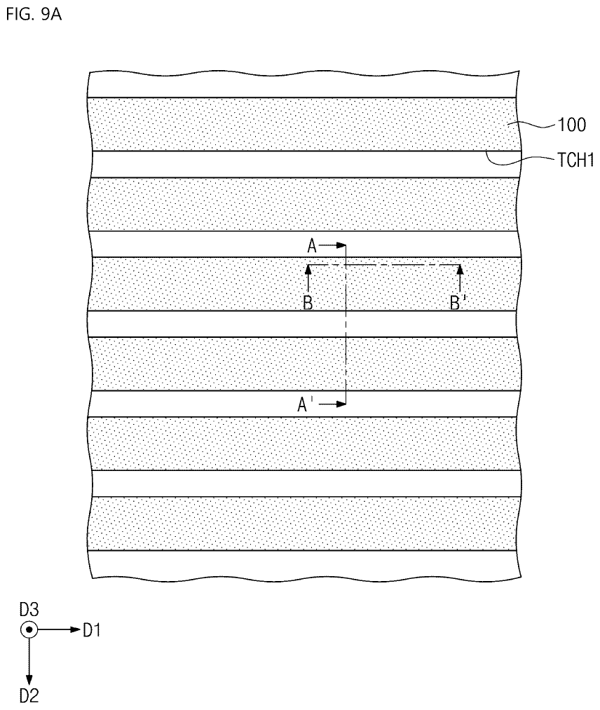

FIGS. 8A, 9A, 10A to 22A are plan views showing a method of manufacturing a semiconductor memory device according to some example embodiments of the present application. FIGS. 8B, 9B, 10B to 22B are cross-sectional views taken along lines A-A′ and B-B′ of FIGS. 8A to 22A, respectively.

Referring to FIGS. 8A and 8B, a first substrate 100 may be prepared. The first substrate 100 may be, for example, a silicon substrate, a germanium substrate, and/or a silicon-germanium substrate. In addition, the first substrate 100 may have a silicon on insulator (SOI) structure.

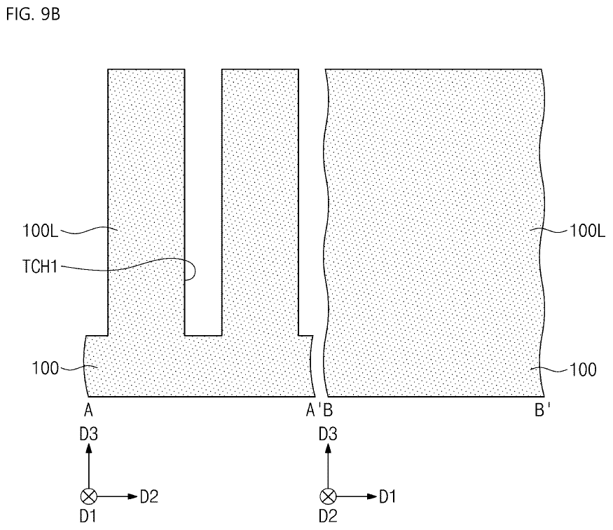

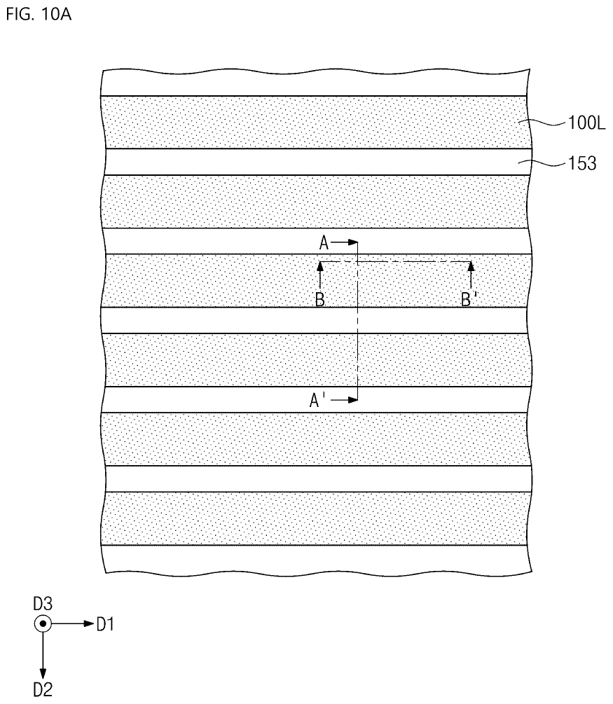

Referring to FIGS. 9A and 9B, a patterning process may be performed on an upper surface of the first substrate 100 to form first trenches TCH1. The first trenches TCH1 may extend within the first substrate 100 in the first direction D1, and each of the first trenches TCH1 may be arranged in the second direction D2.

The adjacent first trenches TCH1 may define a preliminary active line 100L. More specifically, a plurality of first trenches TCH1 arranged in the second direction D2 may be formed to define the preliminary active lines 100L between the adjacent first trenches TCH1. That is, the preliminary active lines 100L may be a portion of the patterned first substrate 100. The preliminary active lines 100L may extend in the first direction D1, and each of the preliminary active lines 100L may be arranged in the second direction D2.

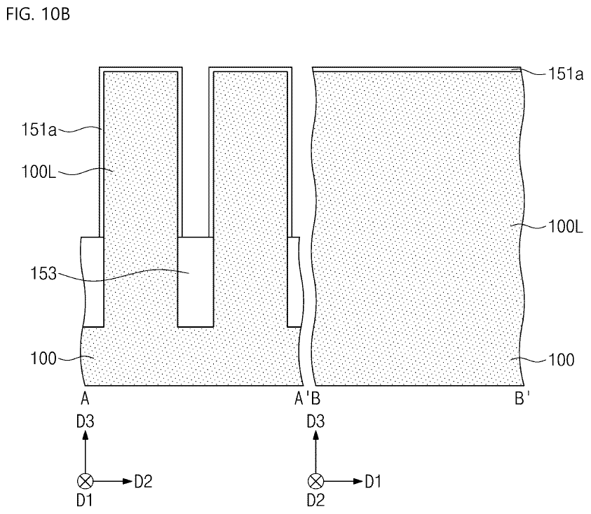

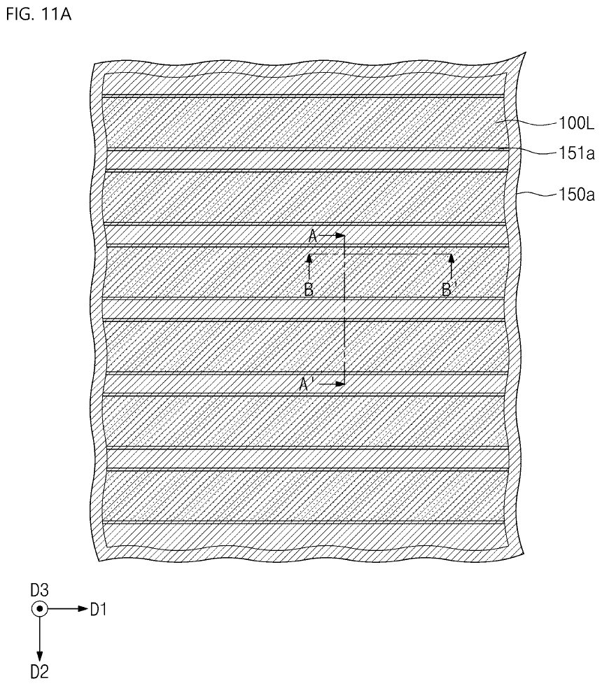

Referring to FIGS. 10A and 10B, a back gate capping film may be formed on the preliminary active lines 100L and inner surfaces of the first trenches TCH1, and a portion of the back gate capping film may be removed to form the back gate capping patterns 153. The back gate capping patterns 153 may be formed through an etch-back process.

Subsequently, a back gate insulation film 151a may be formed on the preliminary active lines 100L and the back gate capping patterns 153. The back gate insulation film 151a may be formed through a thermal oxidation process, but is not limited thereto. The back gate insulation film 151a may be formed, for example, through a deposition process. Although not shown, the back gate insulation film 151a may be conformally formed on the preliminary active lines 100L and the back gate capping patterns 153 to cover upper surfaces of the back gate capping patterns 153.

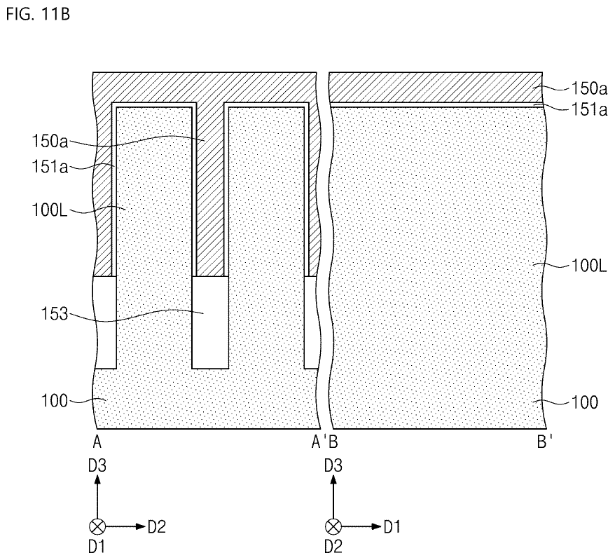

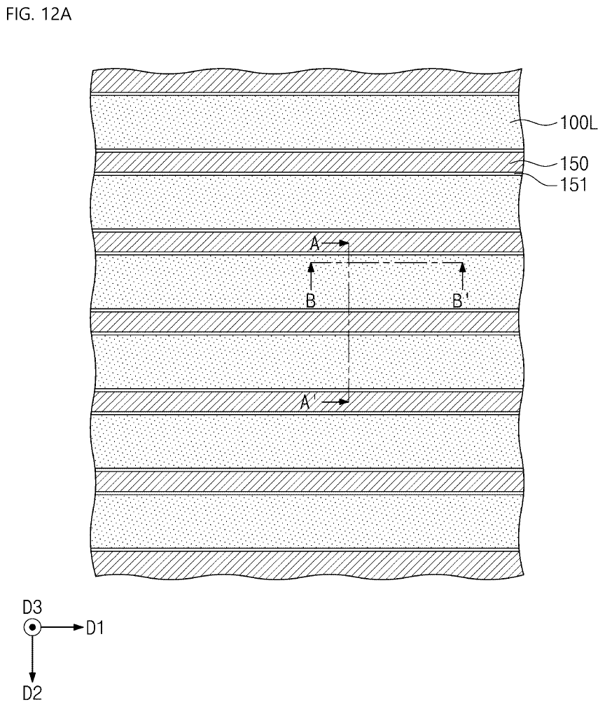

Referring to FIGS. 11A and 11B, a back gate line film 150a may be formed on the back gate insulation film 151a and the back gate capping patterns 153. The back gate line film 150a may fill the first trenches TCH1. The formation of the back gate line film 150a may be performed through at least one of an oxidation process or a deposition process.

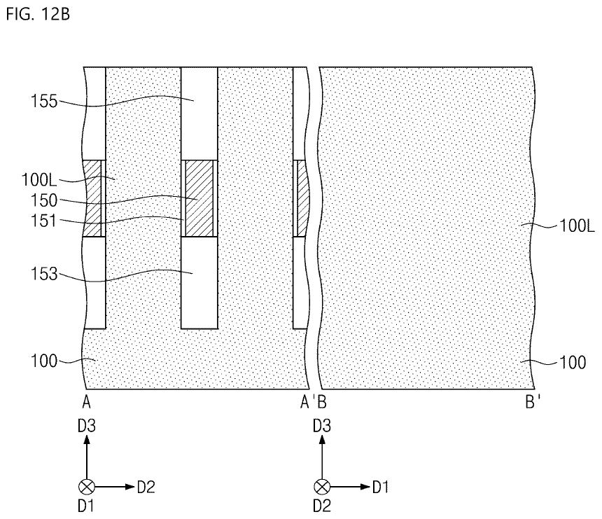

Referring to FIGS. 12A and 12B, an etching process may be performed on the back gate line film 150a to form the back gate lines 150 and the back gate insulation patterns 151. The etching process may be an etch-back process. The back gate lines 150 may be provided between the back gate insulation patterns 151 in a plan view, and each of the back gate lines 150 may extend in the first direction D1.

Subsequently, a first dielectric film may be formed on the preliminary active lines 100L, the back gate insulation patterns 151, and the back gate lines 150 to fill the first trenches TCH1. The formation of the first dielectric film may be performed through at least one of an oxidation process or a deposition process. Thereafter, an etching process may be performed on the first dielectric film to expose the preliminary active lines 100L. The etching process may be performed through a chemical mechanical polishing (CMP) process. Therefore, the first dielectric patterns 155 may be formed. Each of the first dielectric patterns 155 may be formed on the back gate insulation patterns 151 and the back gate line 150 that are present within each of the first trenches TCH1.

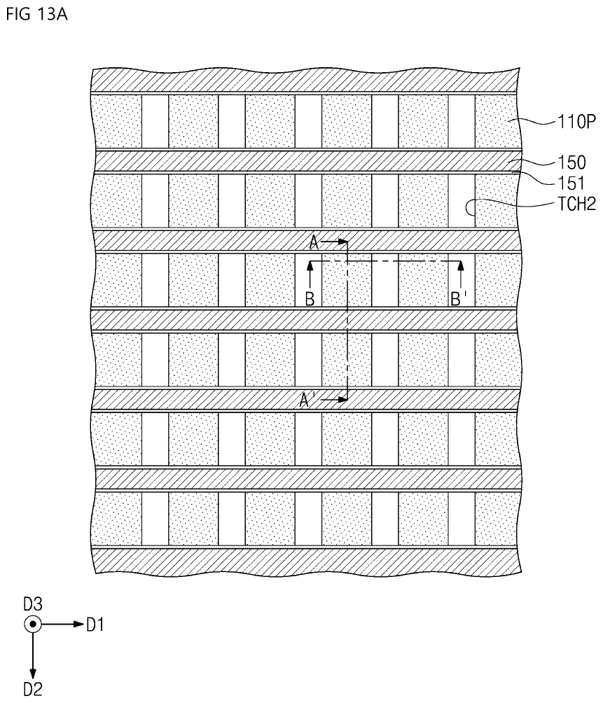

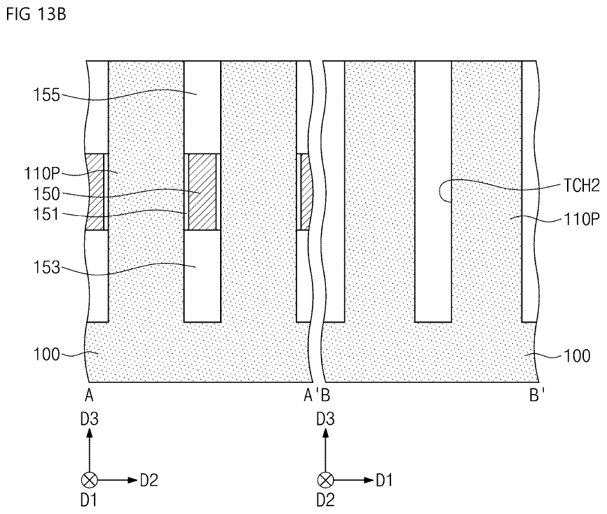

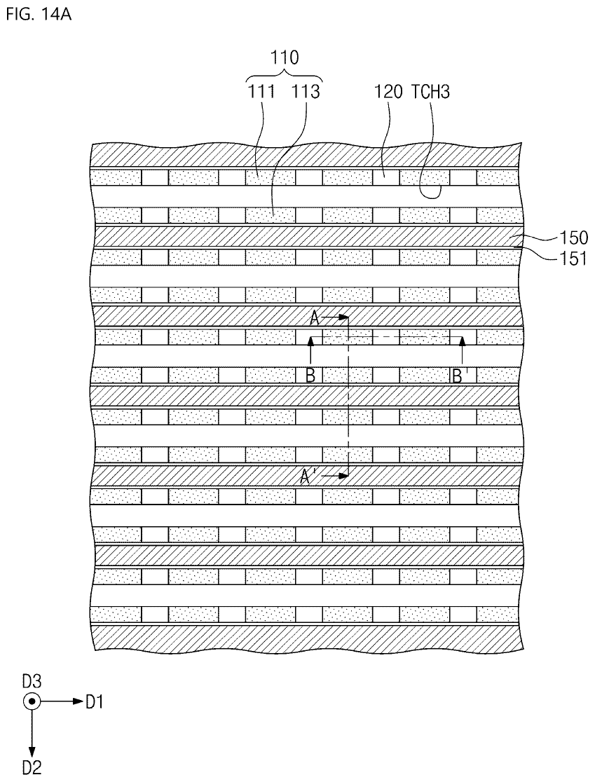

Referring to FIGS. 13A and 13B, after forming an etch mask covering portions of the preliminary active lines 100L, a patterning process may be performed on the preliminary active lines 100L to form second trenches TCH2. The second trenches TCH2 may extend from upper surfaces of the preliminary active lines 100L toward a lower surface of the first substrate 100 and extend in the second direction D2 in a plan view. The second trenches TCH2 may cross the first trenches TCH1 and the preliminary active lines 100L. Therefore, preliminary active patterns 110P may be formed. The preliminary active patterns 110P may be arranged in the first direction D1 and the second direction D2 to form rows and columns.

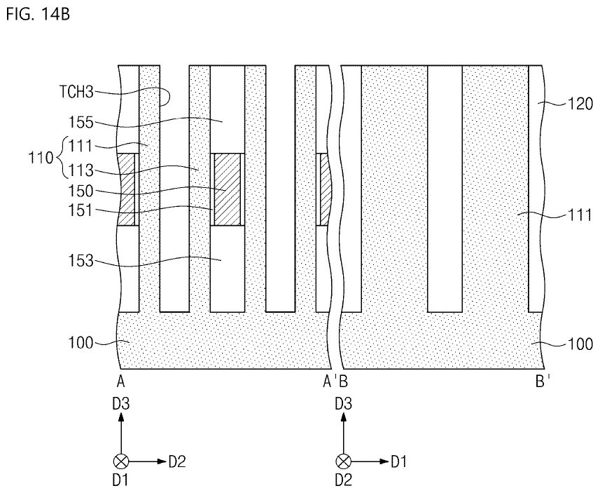

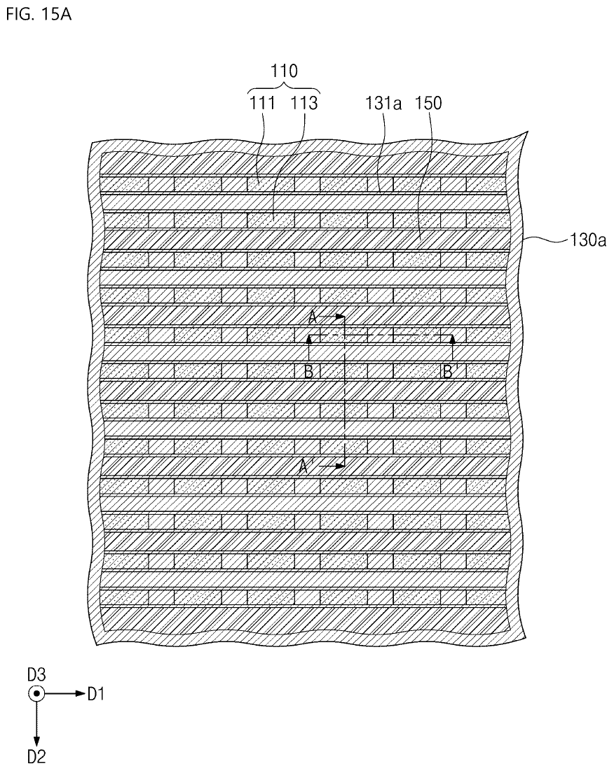

Referring to FIGS. 14A and 14B, the separation insulation patterns 120 may be formed within the second trenches TCH2. The formation of the separation insulation patterns 120 may be performed through at least one of an oxidation process or a deposition process.

Subsequently, a patterning process may be performed on the preliminary active patterns 110P to form third trenches TCH3 and the active patterns 110. The third trenches TCH3 may extend in the first direction D1, and each of the third trenches TCH3 may be arranged in the second direction D2. In addition, each of the active patterns 110 may include the first and second vertical semiconductor patterns 111 and 113 that are spaced apart from each other. More specifically, the third trenches TCH3 may extend in the first direction D1 to be formed between the first vertical semiconductor patterns 111 and the second vertical semiconductor patterns 113 of the active patterns 110 of each of the rows. Meanwhile, levels of bottom surfaces of the third trenches TCH3 may be lower than levels of lower surfaces of the first and second vertical semiconductor patterns 111 and 113.

Here, the patterning of the preliminary active patterns 110P may include patterning the preliminary active patterns 110P and the separation insulation patterns 120 to form the third trenches TCH3 and the active patterns 110. More specifically, each of the third trenches TCH3 may be formed between the first vertical semiconductor patterns 111 and the second vertical semiconductor patterns 113 of the active patterns 110 of each of the rows and within the separation insulation patterns 120 of each of the rows.

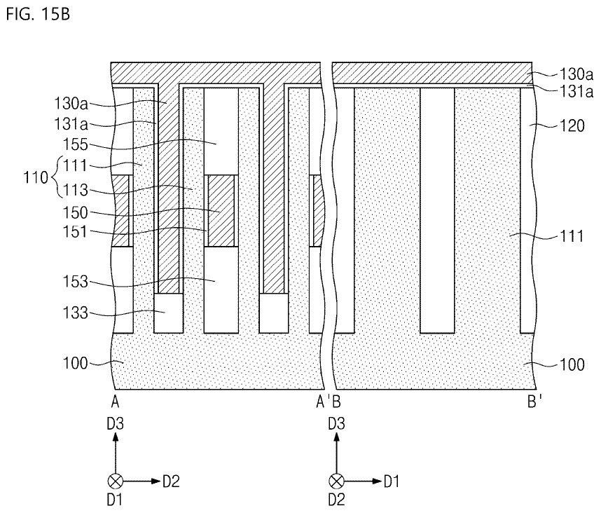

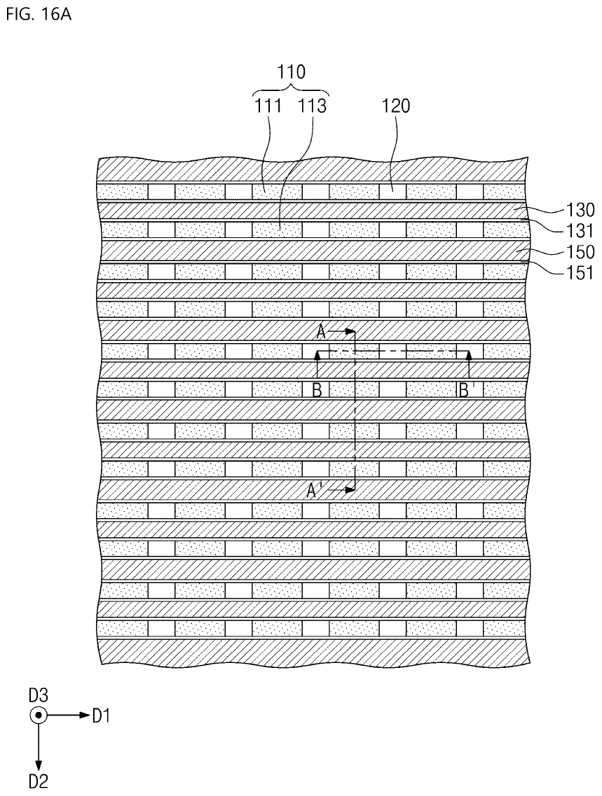

Referring to FIGS. 15A and 15B, a word line capping film may be formed on the active patterns 110 and inner surfaces of the third trenches TCH3, and portions of the word line capping film may be removed to form the word line capping patterns 133. The word line capping patterns 133 may be formed through an etch-back process.

Subsequently, a word line insulation film 131a may be formed on the active patterns 110 and the word line capping patterns 133. The word line insulation film 131a may be formed through a thermal oxidation process, but is not limited thereto. The word line insulation film 131a may be formed, for example, through a deposition process. Although not shown, in some example embodiments, the word line insulation film 131a may be conformally formed on the active patterns 110 and the word line capping patterns 133 to cover upper surfaces of the word line capping patterns 133.

A word line film 130a may be formed on the word line insulation film 131a and the word line capping patterns 133. The word line film 130a may fill the third trenches TCH3. The formation of the word line film 130a may be performed through at least one of an oxidation process or a deposition process.

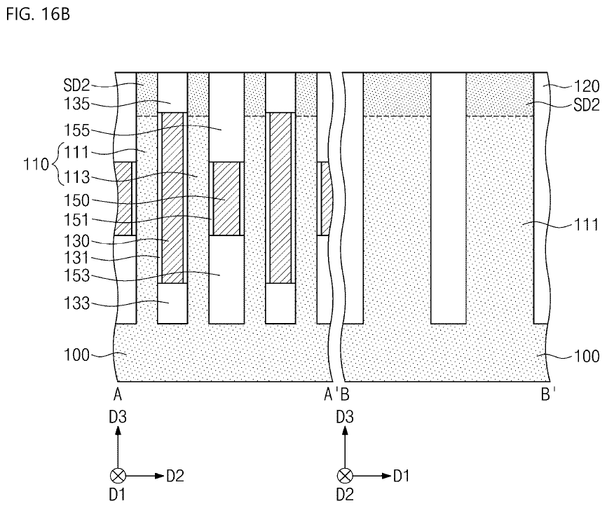

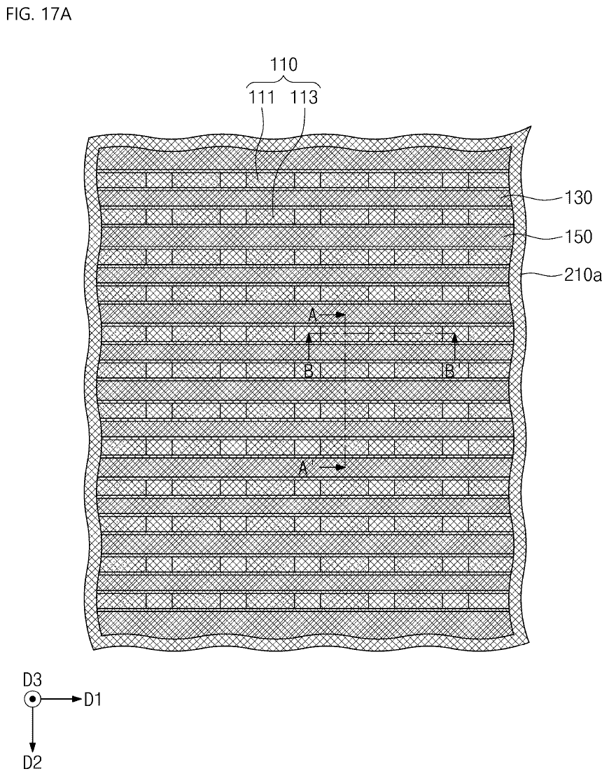

Referring to FIGS. 16A and 16B, an etching process may be performed to form the word lines 130 and the word line insulation patterns 131. The etching process may be an etch-back process. In some example embodiments, each of the word lines 130 may fill the third trenches TCH3 on the word line insulation film 131a. The word lines 130 may be provided between the word line insulation patterns 131 in a plan view and each of the word lines 130 may extend in the first direction D1.

A second dielectric film may be formed on the active patterns 110, the first dielectric patterns 155, the word line insulation patterns 131, and the word lines 130 to fill the third trenches TCH3. The formation of the second dielectric film may be performed through at least one of an oxidation process or a deposition process.

Thereafter, an etching process may be performed on the first substrate 100 to expose the active patterns 110. That is, the upper surface of the first substrate 100 may be ground until upper surfaces of the first and second vertical semiconductor patterns 111 and 113 are exposed. The etching process may be performed through a chemical mechanical polishing process. Therefore, the second dielectric patterns 135 may be formed. Each of the second dielectric patterns 135 may be formed on the word line insulation patterns 131 and the word lines 130 that are present within each of the third trenches TCH3.

Subsequently, an ion implantation process may be performed on an upper end portion of each of the first and second vertical semiconductor patterns 111 and 113 to form the second source/drain region SD2.

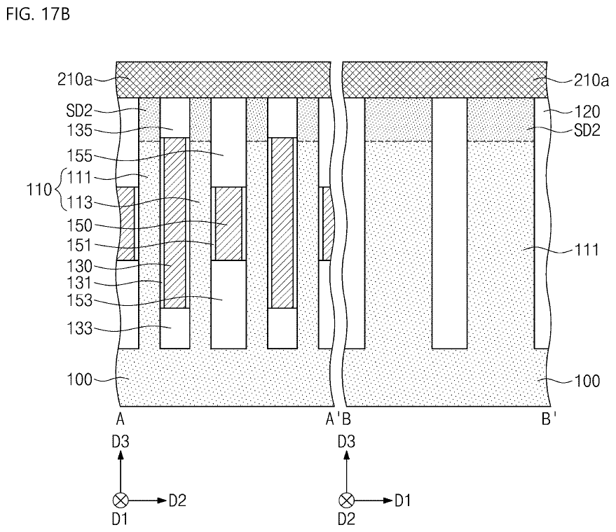

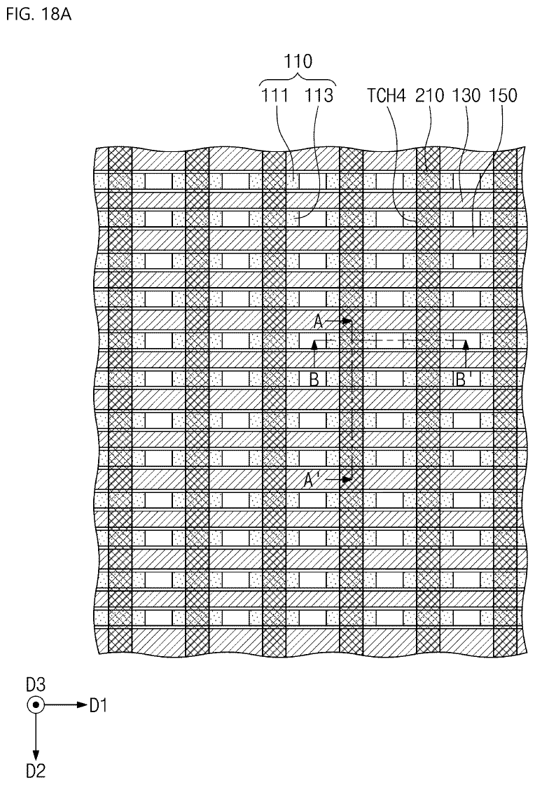

Referring to FIGS. 17A and 17B, a bit line film 210a may be formed on the first and second vertical semiconductor patterns 111 and 113 and the first and second dielectric patterns 155 and 135. Although not shown, the bit line film 210a may include an embedded conductive film, a contact film, a metal film, and/or a hard mask film. More specifically, the embedded conductive film, the contact film, the metal film, and the hard mask film may be sequentially formed on the first and second vertical semiconductor patterns 111 and 113 and the first and second dielectric patterns 155 and 135. The formation of the bit line film 210a may be performed through at least one of an oxidation process or a deposition process.

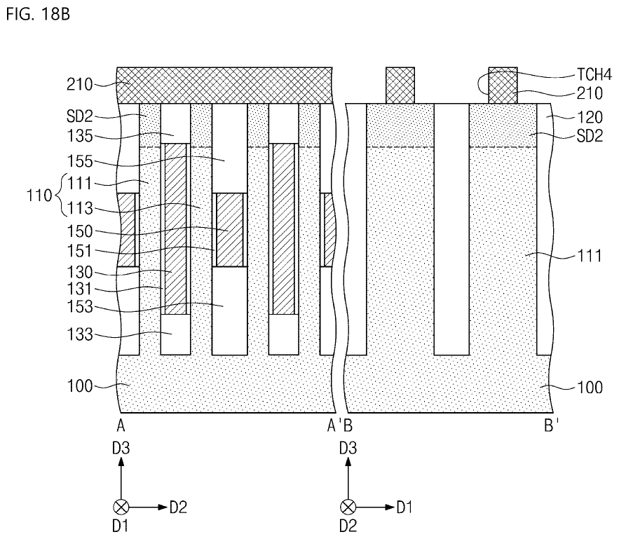

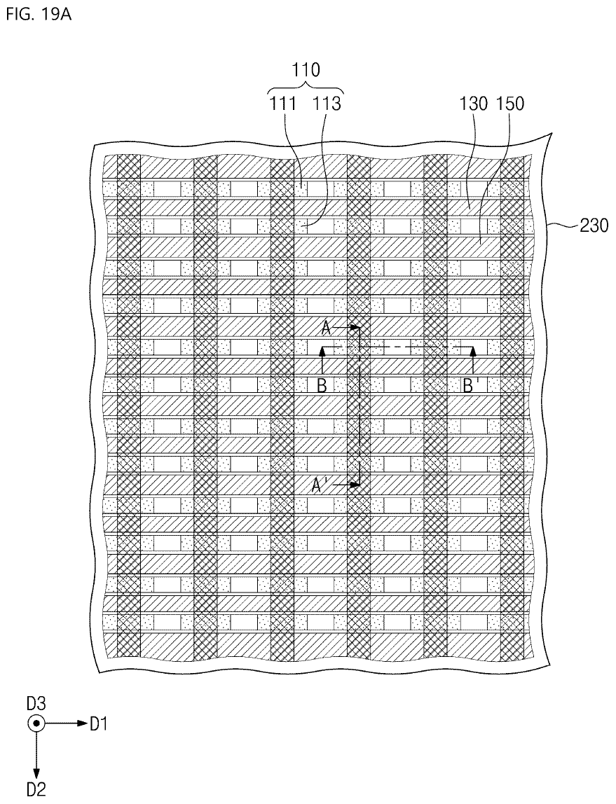

Referring to FIGS. 18A and 18B, a mask pattern having a line shape extending in the second direction D2 may be formed on the bit line film 210a, and the bit line film 210a may be anisotropically etched using the mask pattern. Accordingly, fourth trenches TCH4 extending in the second direction D2 may be formed. As a result, the bit lines 210 extending in the second direction D2 may be formed. Each of the bit lines 210 may be spaced apart in the first direction D1 by the fourth trenches TCH4 in a plan view.

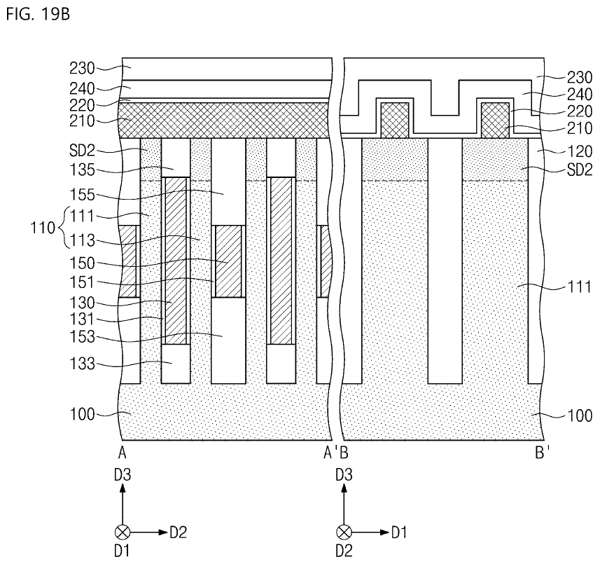

Referring to FIGS. 19A and 19B, after the bit lines 210 are formed, the bit line insulation pattern 220 may be conformally formed on the bit lines 210 and the fourth trenches TCH4. A formation thickness of the bit line insulation pattern 220 may be smaller than half an interval between the adjacent bit lines 210. Subsequently, the dielectric film 240 may be conformally formed on the bit line insulation pattern 220. Thereafter, the gap structure 230 may be formed on the dielectric film 240 to fill the fourth trenches TCH4. The formation of the bit line insulation pattern 220, the dielectric film 240, and the gap structure 230 may be performed through at least one of an oxidation process or a deposition process.

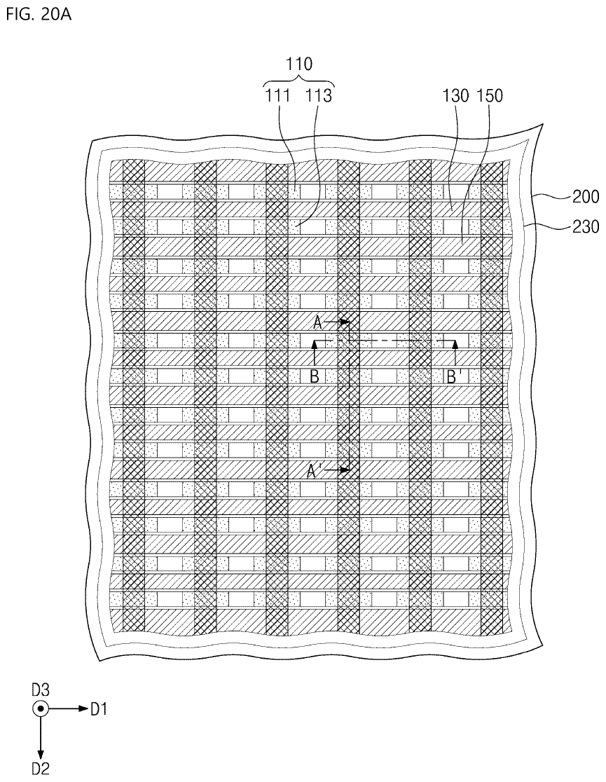

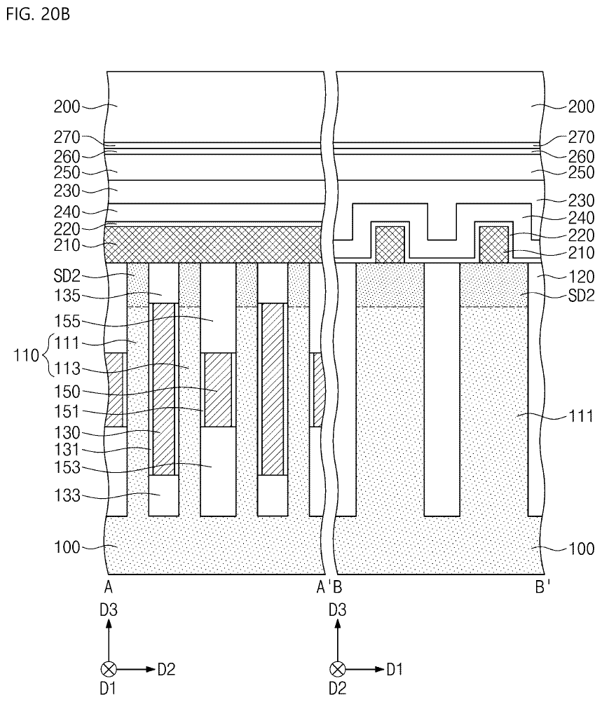

Referring to FIGS. 20A and 20B, after an interlayer insulation film 250 is formed on the gap structure 230, a first bonding film 260 may be formed on the interlayer insulation film 250.

In addition, a second bonding film 270 may be formed on a second substrate 200, and after flipping the second substrate 200 over, the second bonding film 270 may come into contact with the first bonding film 260 to bond the first substrate 100 and the second substrate 200 to each other.

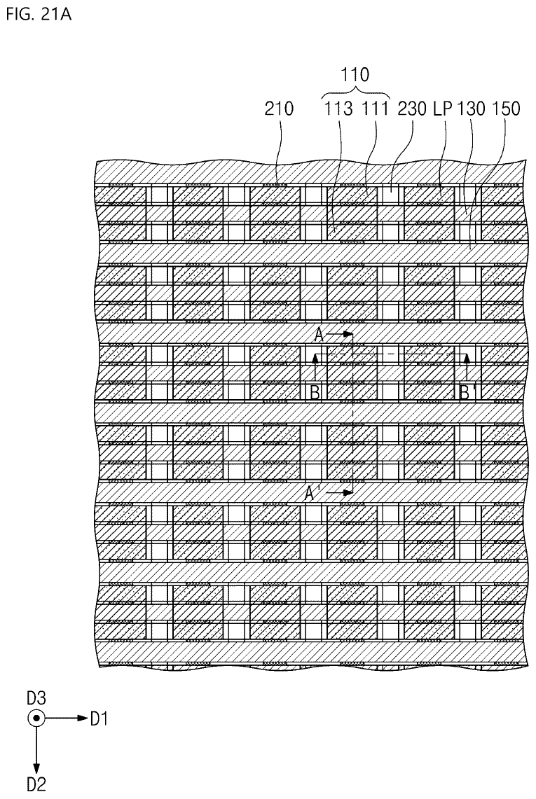

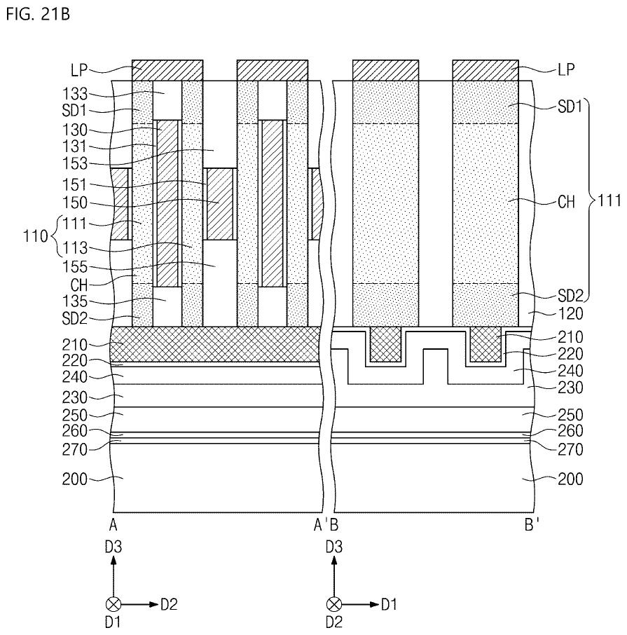

Referring to FIGS. 21A and 21B, the bonded first and second substrates 100 and 200 may be flipped over. Thereafter, an etching process may be performed so that the upper surface of the first substrate 100 is polished to expose the first and second vertical semiconductor patterns 111 and 113. That is, the upper surface of the first substrate 100 may be ground until the upper surfaces of the first and second vertical semiconductor patterns 111 and 113 are exposed. The etching process may be performed through a chemical mechanical polishing process.

Subsequently, an ion implantation process may be performed on the upper end portion of each of the first and second vertical semiconductor patterns 111 and 113 to form the first source/drain region SD1. Therefore, the channel region CH may be defined between the first source/drain region SD1 and the second source/drain region SD2.

In some example embodiments, a conductive film may be formed on the first substrate 100, and the landing pads LP may be formed by patterning portions of the conductive film.

More specifically, after forming the conductive film, a recess may be formed using a mask pattern, and an insulating material may be embedded within the recess to form the pad separation pattern 320. Here, an upper surface of the pad separation pattern 320 may be coplanar or substantially coplanar with an upper surface of the landing pad LP.

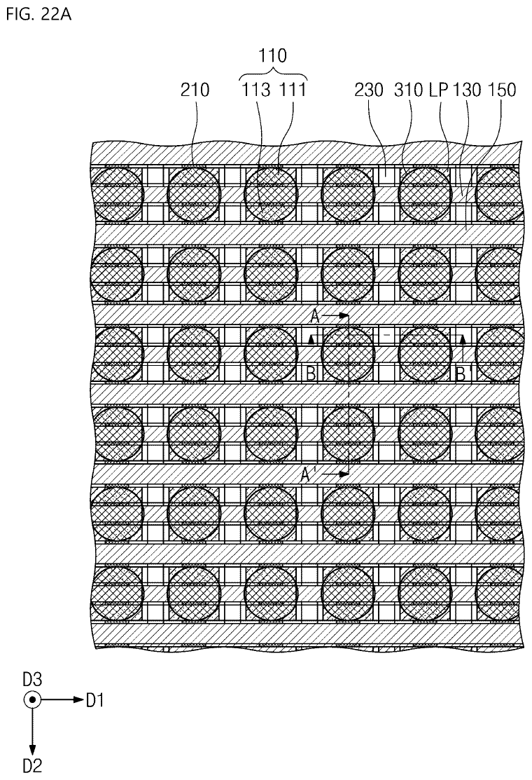

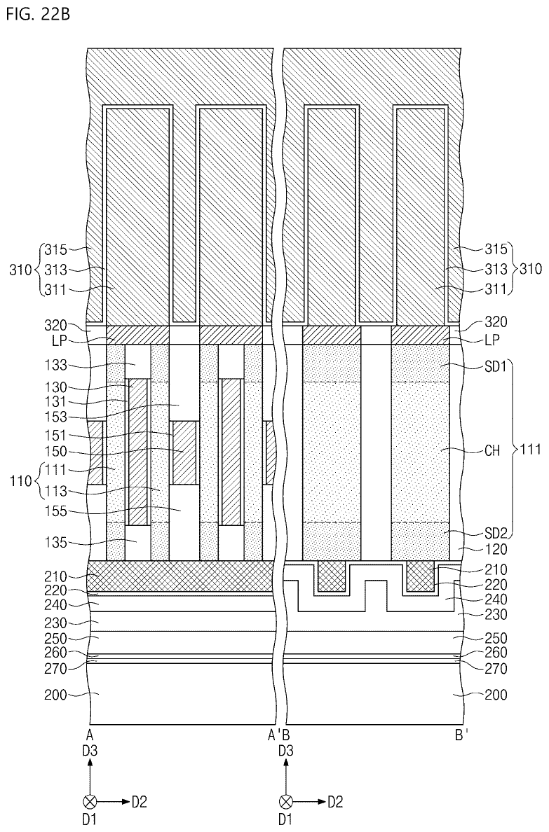

Referring to FIGS. 22A and 22B, the capacitors 310 as the data storage patterns DSP may be formed on the landing pads LP.

More specifically, the storage electrodes 311 may be formed on the landing pads LP. Thereafter, the capacitor dielectric film 313 may be formed to conformally cover surfaces of the storage electrodes 311. Subsequently, the plate electrode 315 may be formed on the capacitor dielectric film 313. The sequentially stacked storage electrodes 311 and capacitor dielectric film 313 may form the capacitor 310 together with the plate electrode 315.

Referring back to FIGS. 5 and 6, the semiconductor memory device according to some example embodiments of the present application may be manufactured by polishing the bonded second substrate 200.

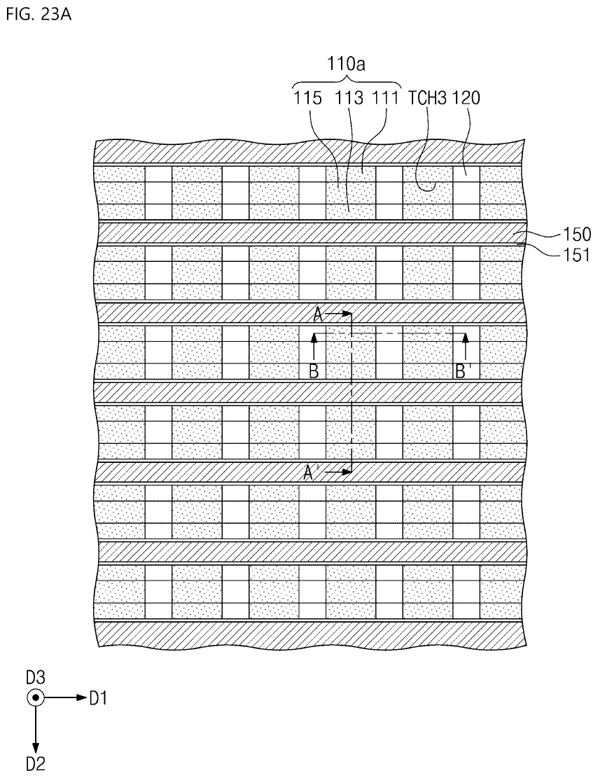

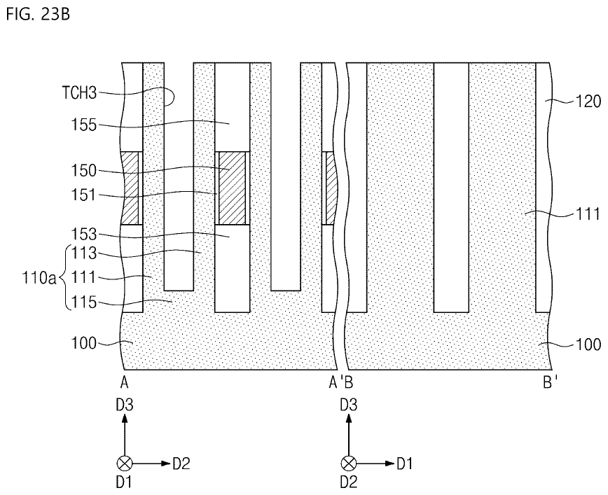

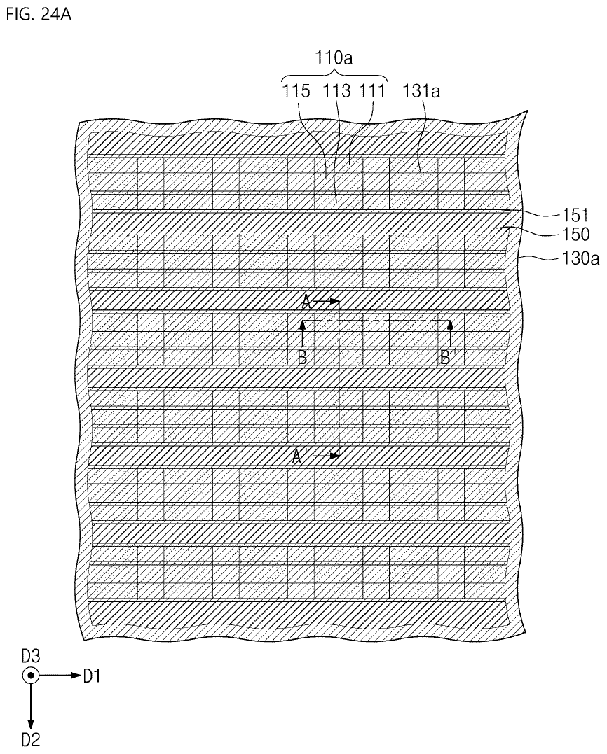

FIGS. 23A, 24B to 28A are plan views showing a method of manufacturing a semiconductor memory device according to some example embodiments of the present application. FIGS. 23B, 24B to 28B are cross-sectional views taken along lines A-A′ and B-B′ of FIGS. 23A to 28A, respectively. For convenience of explanation, hereinafter, differences from the above-described methods of manufacturing the semiconductor memory device will be described.

Referring to FIGS. 23A and 23B, a patterning process may be performed on the preliminary active patterns 110P to form the third trenches TCH3 and the active patterns 110a. The third trenches TCH3 may extend in the first direction D1, and each of the third trenches TCH3 may be arranged in the second direction D2. In addition, each of the active patterns 110a may include the first and second vertical semiconductor patterns 111 and 113 and the connecting portion 115. More specifically, the third trenches TCH3 may extend in the first direction D1 to be formed among the first vertical semiconductor patterns 111, the second vertical semiconductor patterns 113, and the connecting portions 115 of the active patterns 110a of each of the rows.

In some example embodiments, levels of bottom surfaces of the third trenches TCH3 may be higher than the levels of the lower surfaces of the first and second vertical semiconductor patterns 111 and 113. Therefore, in each of the active patterns 110a, the connecting portion 115 may be provided between lower end portions of the first and second vertical semiconductor patterns 111 and 113 to be integrally connected to the lower end portions.

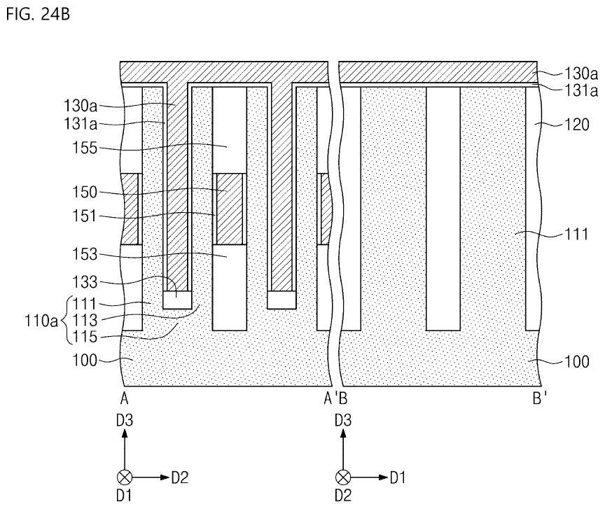

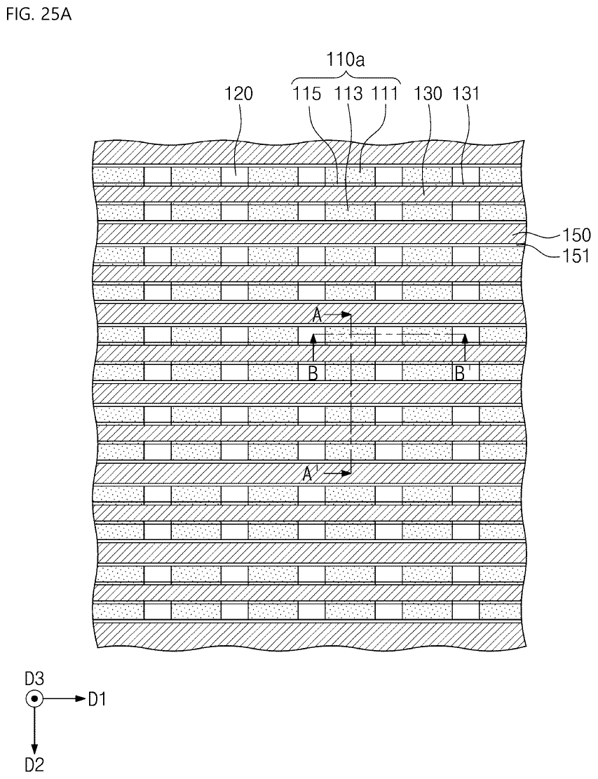

Referring to FIGS. 24A and 24B, a word line capping film may be formed on the active patterns 110a and inner surfaces of the third trenches TCH3, and portions of the word line capping film may be removed to form the word line capping patterns 133.

Subsequently, the word line insulation film 131a may be formed on the active patterns 110a and the word line capping patterns 133, and the word line film 130a may be formed on the word line insulation film 131a and the word line capping patterns 133.

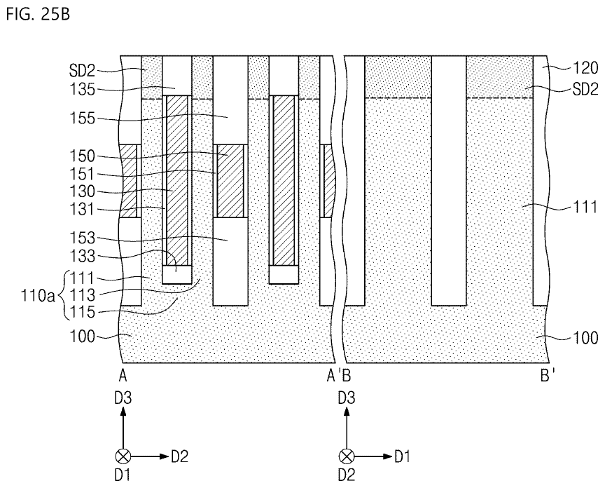

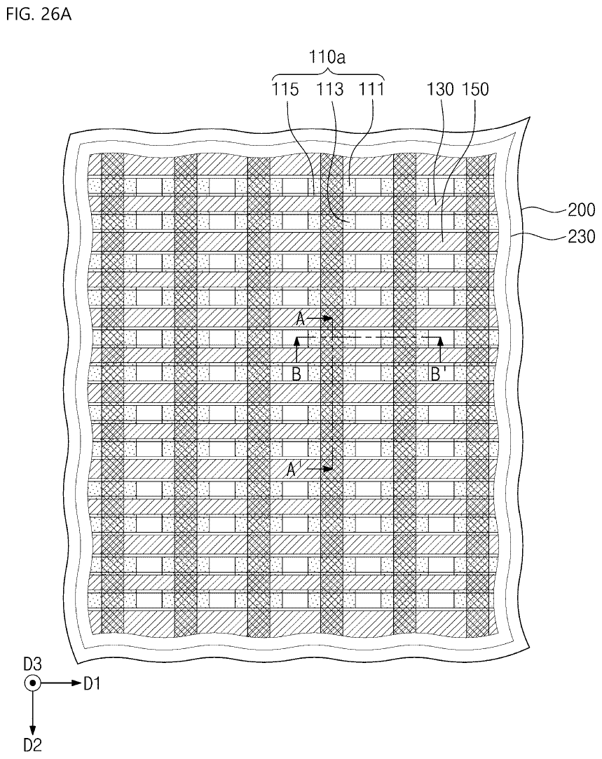

Referring to FIGS. 25A and 25B, an etch-back process may be performed to form the word lines 130 and the word line insulation patterns 131. A second dielectric film may be formed on the active patterns 110a, the first dielectric patterns 155, the word line insulation patterns 131, and the word lines 130 to fill the third trenches TCH3. Thereafter, a chemical mechanical polishing process may be performed on the first substrate 100 to expose the active patterns 110a. Therefore, the second dielectric patterns 135 may be formed. Each of the second dielectric patterns 135 may be formed on the word line insulation patterns 131 and the word lines 130 that are present within each of the third trenches TCH3.

Subsequently, an ion implantation process may be performed on an upper end portion of each of the first and second vertical semiconductor patterns 111 and 113 to form the second source/drain region SD2.

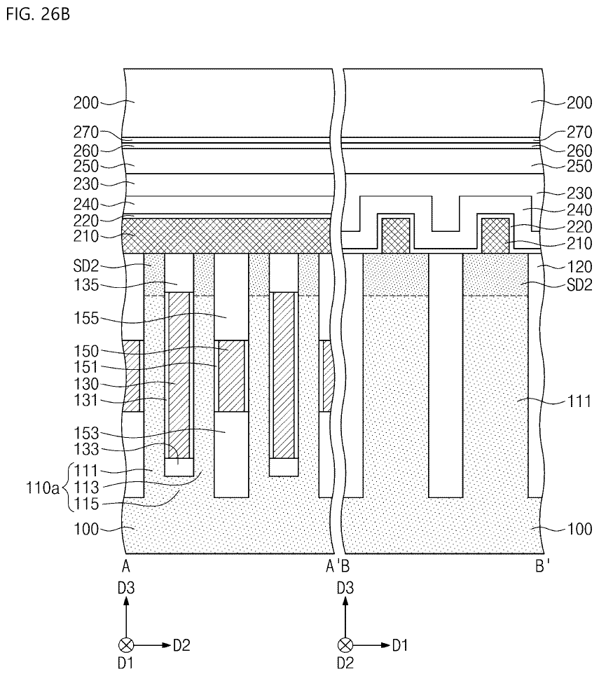

Referring to FIGS. 26 Aand 26B, the bit line film 210a may be formed on the first vertical semiconductor patterns 111, the second vertical semiconductor patterns 113, the connecting portions 115, the first dielectric patterns 155, and the second dielectric patterns 135. The bit line film 210a may be anisotropically etched to form the bit lines 210 extending in the second direction D2.

A deposition process or an oxidation process may be performed on the bit lines 210 to form the bit line insulation pattern 220, the dielectric film 240, and the gap structure 230.

Subsequently, after forming the interlayer insulation film 250 on the gap structure 230, the first bonding film 260 may be formed on the interlayer insulation film 250, and the second bonding film 270 may come into contact with the first bonding film 260 to bond the first substrate 100 and the second substrate 200 to each other.

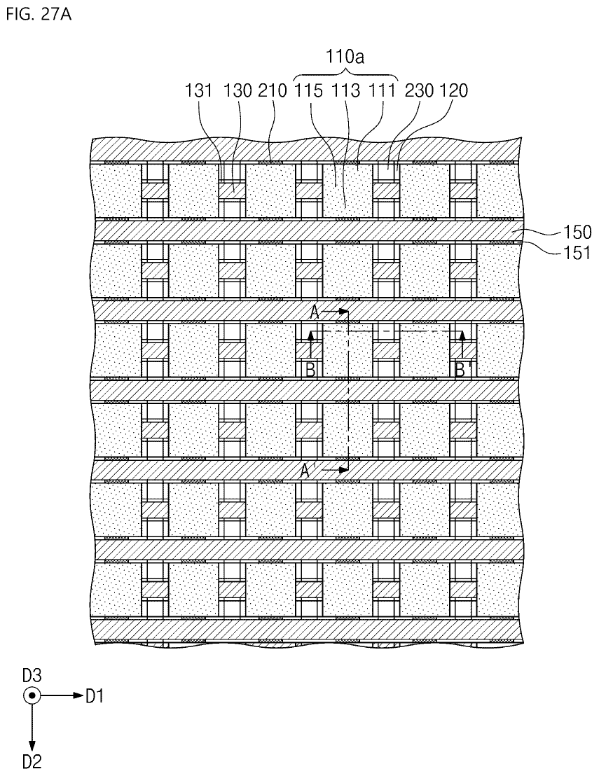

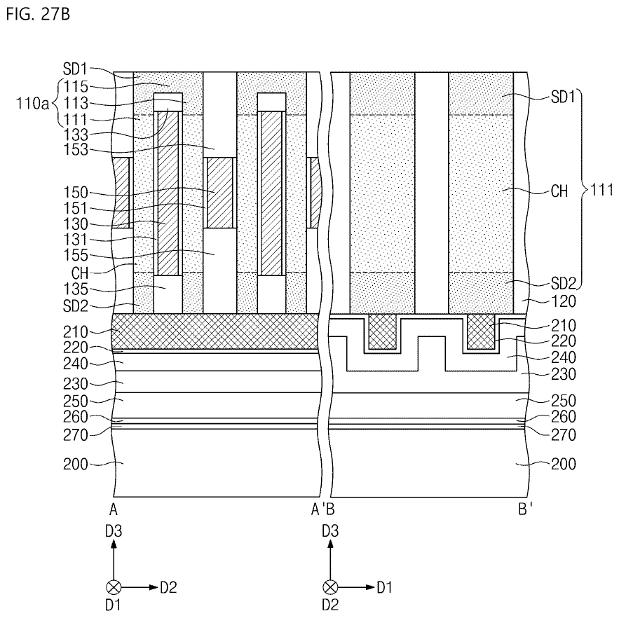

Referring to FIGS. 27A and 27B, the bonded first and second substrates 100 and 200 may be flipped over, and a chemical mechanical polishing process may be performed to grind an upper surface of the first substrate 100 so that the first and second vertical semiconductor patterns 111 and 113 and the connecting portions 115 are exposed.

Subsequently, an ion implantation process may be performed on an upper end portion of each of the first and second vertical semiconductor patterns 111 and 113 and the connecting portion 115 to form the first source/drain region SD1. Therefore, the channel region CH may be defined between the first source/drain region SD1 and the second source/drain region SD2 in each of the first and second vertical semiconductor patterns. In addition, the connecting portion 115 may include the first source/drain region SD1.

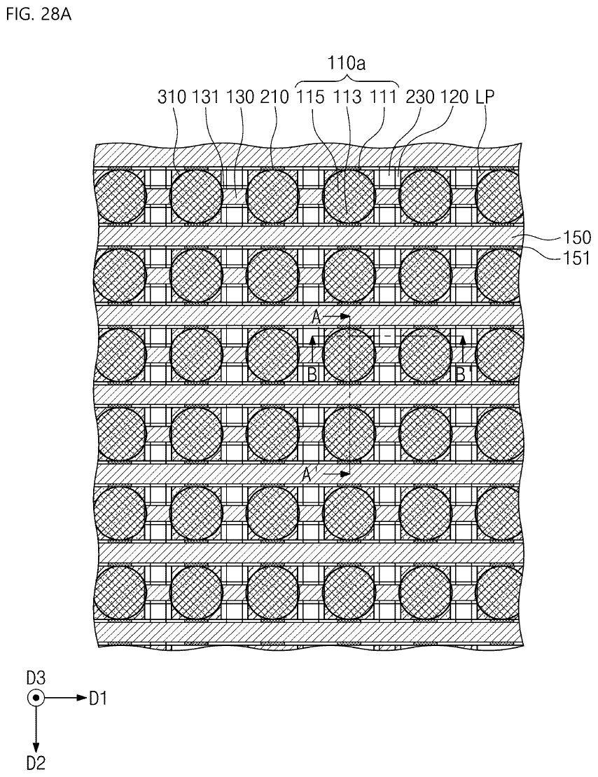

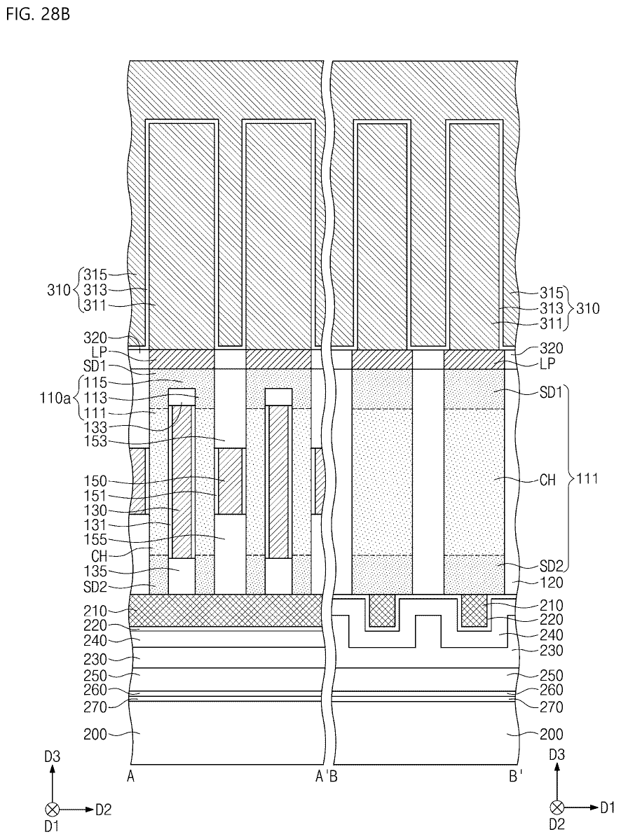

Referring to FIGS. 28A and 28B, a conductive film may be formed on the first substrate 100, a recess may be formed using a mask pattern on the conductive film, and an insulating material may be embedded within the recess to form the pad separation pattern 320. In this case, the landing pads LP may be formed between the pad separation patterns 320. An upper surface of the pad separation pattern 320 may be coplanar or substantially coplanar with an upper surface of the landing pad LP.

Subsequently, the storage electrodes 311 may be formed on the landing pads LP. Thereafter, the capacitor dielectric film 313 may be formed to conformally cover surfaces of the storage electrodes 311. Subsequently, the plate electrode 315 may be formed on the capacitor dielectric film 313. The sequentially stacked storage electrodes 311 and capacitor dielectric film 313 may form the capacitor 310 together with the plate electrode 315.

Referring back to FIG. 7, the semiconductor memory device according to some example embodiments of the present application may be manufactured by polishing the bonded second substrate 200.

According to some example embodiments of the present application, active patterns, each including first and second vertical semiconductor patterns, can be provided, and the first and second vertical semiconductor patterns can include channel regions. In addition, a word line can be provided between the first and second vertical semiconductor patterns of each of the active patterns. Therefore, the channel regions can each be provided on both side surfaces of the word line. In addition, a back gate line can be provided between the adjacent active patterns. As a result, the word line and the back gate line can each be provided on one of both side surfaces of each of the first and second vertical semiconductor patterns, allowing control of the leakage current. Moreover, adjacent selector devices in memory cells can share the back gate line, thereby increasing integration.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

Although the present application has been described above with reference to some example embodiments of the present application, those skilled in the art or those having ordinary skill in the art will be able to understand that the present application may be modified and changed in various ways without departing from the spirit and technical scope of the present application as described in the appended claims.

Therefore, the technical scope of the present application should not be limited to the contents described in the detailed descriptions of the specification, but should be defined by the patent claims.

What is claimed is:

1. A semiconductor memory device comprising:
active patterns arranged in a first direction and a second direction intersecting the first direction to form rows and columns, each of the active patterns including first and second vertical semiconductor patterns spaced apart from each other and extending in a third direction perpendicular to the first and second directions;
bit lines arranged in the first direction, each extending in the second direction, and each connected to lower surfaces of the first and second vertical semiconductor patterns of the active patterns of each of the columns;
word lines arranged in the second direction, each extending in the first direction, and between the first vertical semiconductor patterns and the second vertical semiconductor patterns of the active patterns of each of the rows;
word line insulation patterns each between each of the word lines and the active patterns of each of the rows, the word line insulation patterns not covering upper surfaces of the word lines;
back gate lines arranged in the second direction, each extending in the first direction, and between the adjacent rows; and
back gate insulation patterns each between each of the back gate lines and the active patterns and extending in the first direction.

2. The semiconductor memory device of claim 1, wherein
each of the first and second vertical semiconductor patterns includes a channel region, a first source/drain region, and a second source/drain region,
the first source/drain region is in an upper end portion of each of the first and second vertical semiconductor patterns,
the second source/drain region is in a lower end portion of each of the first and second vertical semiconductor patterns, and
the channel region is between the first source/drain region and the second source/drain region.

3. The semiconductor memory device of claim 1, further comprising
a data storage pattern on upper surfaces of the first and second vertical semiconductor patterns of each of the active patterns and electrically connected to the first and second vertical semiconductor patterns.

4. The semiconductor memory device of claim 3, wherein the data storage pattern is a capacitor.

5. The semiconductor memory device of claim 1, further comprising word line capping patterns each covering each of the upper surfaces of the word lines and extending in the first direction,
wherein upper surfaces of the word line capping patterns are coplanar with upper surfaces of the first and second vertical semiconductor patterns.

6. The semiconductor memory device of claim 5, wherein the word line insulation patterns include a different material from the word line capping patterns.

7. The semiconductor memory device of claim 1, further comprising back gate capping patterns each covering each of upper surfaces of the back gate lines and extending in the first direction.

8. The semiconductor memory device of claim 1, wherein the first and second vertical semiconductor patterns are in a monocrystalline state.

9. A semiconductor memory device comprising:
active patterns arranged in a first direction and a second direction intersecting the first direction to form rows and columns, each of the active patterns including first and second vertical semiconductor patterns spaced apart from each other and extending in a third direction perpendicular to the first and second directions and a connecting portion between upper end portions of the first and second vertical semiconductor patterns and integrally connected to the upper end portions;
bit lines arranged in the first direction, each extending in the second direction, and each connected to lower surfaces of the first and second vertical semiconductor patterns of the active patterns of each of the columns;
word lines arranged in the second direction, each extending in the first direction, and between the first vertical semiconductor patterns and the second vertical semiconductor patterns of the active patterns of each of the rows;
word line insulation patterns each between each of the word lines and the active patterns of each of the rows;
back gate lines arranged in the second direction, each extending in the first direction, and between the adjacent rows; and
back gate insulation patterns each between each of the back gate lines and the active patterns and extending in the first direction.

10. The semiconductor memory device of claim 9, wherein
the first and second vertical semiconductor patterns include channel regions, a first source/drain region, and second source/drain regions,
the first source/drain region is in the upper end portions of the first and second vertical semiconductor patterns and the connecting portion,
the second source/drain regions are each in each of lower portions of the first and second vertical semiconductor patterns, and
the channel regions are defined between the first source/drain region and the second source/drain regions.

11. The semiconductor memory device of claim 9, further comprising word line capping patterns each covering each of upper surfaces of the word lines and extending in the first direction,
wherein upper surfaces of the word line capping patterns are coplanar with lower surfaces of the connecting portions.

12. The semiconductor memory device of claim 9, further comprising back gate capping patterns each covering each of upper surfaces of the back gate lines and extending in the first direction.

13. A method of manufacturing a semiconductor memory device comprising:
forming first trenches extending in a first direction within a substrate to define preliminary active lines and forming back gate lines each filling each of the first trenches;
forming second trenches crossing the first trenches and the preliminary active lines within the substrate to form preliminary active patterns, the preliminary active patterns being arranged in a first direction and a second direction intersecting the first direction to form rows and columns;
patterning the preliminary active patterns to form third trenches extending in the first direction and active patterns, each of the active patterns including first and second vertical semiconductor patterns spaced apart from each other, and each of the third trenches being formed between the first vertical semiconductor patterns and second vertical semiconductor patterns of the active patterns of each of the rows;
forming a word line insulation film on the substrate having the third trenches and the active patterns; and
forming word lines each filling each of the third trenches on the word line insulation film.

14. The method of claim 13, further comprising, before the forming of the third trenches, forming separation insulation patterns within the second trenches,
wherein
the patterning of the preliminary active patterns includes patterning the preliminary active patterns and the separation insulation patterns to form the third trenches and the active patterns, and
each of the third trenches is formed between the first vertical semiconductor patterns and second vertical semiconductor patterns of the active patterns of each of the rows and within the separation insulation patterns of each of the rows.

15. The method of claim 13, further comprising,
before the forming of the word lines, forming word line capping patterns covering upper surfaces of the word lines.

16. The method of claim 13, further comprising:
after the forming of the word lines, grinding a lower surface of the substrate until lower surfaces of the first and second vertical semiconductor patterns are exposed; and
forming bit lines on the lower surfaces of the first and second vertical semiconductor patterns.

17. The method of claim 16, further comprising, after the forming of the bit lines, forming a data storage pattern on upper surfaces of the first and second vertical semiconductor patterns of each of the active patterns.

18. The method of claim 17, wherein the data storage pattern is a capacitor.

19. The method of claim 13, wherein levels of bottom surfaces of the third trenches are lower than levels of lower surfaces of the first and second vertical semiconductor patterns.

20. The method of claim 13, wherein
levels of bottom surfaces of the third trenches are higher than levels of lower surfaces of the first and second vertical semiconductor patterns, and
each of the active patterns further includes a connecting portion between upper end portions of the first and second vertical semiconductor patterns and integrally connected to the upper end portions.
